(19) United States
(12) Patent Application Publication
(10) Pub. No.: US 2023/0363188 A1
(43) Pub. Date: Nov. 9, 2023

(54) SOLID-STATE IMAGING DEVICE AND ELECTRONIC EQUIPMENT

(71) Applicant: SONY SEMICONDUCTOR SOLUTIONS CORPORATION, KANAGAWA (JP)

(72) Inventor: JUNJI NARUSE, KANAGAWA (JP)

(21) Appl. No.: 18/004,898

(22) PCT Filed: Jun. 16, 2021
(86) PCT No.: PCT/JP2021/022769

§ 371 Date: Jan. 10, 2023

(30) Foreign Application Priority Data
Jul. 20, 2020 (JP) 2020-123855

(51) Int. Cl. H10K 39/32; G02B 5/30

(52) U.S. Cl. CPC H10K 39/32; G02B 5/3058; H04N 23/555

(57) ABSTRACT

To provide a solid-state imaging device capable of achieving a further improvement in polarization efficiency.

Provided are a solid-state imaging device including a pixel array unit configured such that a plurality of pixels are arranged two-dimensionally, in which each of the plurality of pixels includes at least a polarizer containing a conductive light shielding material, a photoelectric conversion element that performs photoelectric conversion, and a medium, the medium is disposed around the polarizer, and the medium has a predetermined refractive index n, and a solid-state imaging device including a pixel array unit configured such that a plurality of first pixels and at least one second pixel are arranged two-dimensionally, in which each of the plurality of first pixels includes a photoelectric conversion element that performs photoelectric conversion, the at least one second pixel includes a polarizer containing a conductive light shielding material, a photoelectric conversion element that performs photoelectric conversion, and a medium, a medium is disposed around the polarizer, and the medium has a predetermined refractive index n.

### TECHNICAL FIELD

The present technology relates to a solid-state imaging device and electronic equipment.

### BACKGROUND ART

In recent years, digital cameras and the like have become increasingly widespread, and the current situation is that the demand for solid-state imaging devices (image sensors), which are their core components, is increasing more and more. Under the present circumstances, in terms of the performance of solid-state imaging devices, technical developments are actively being made to achieve high image quality and high functionality.

For example, technology related to an imaging device including pixels (polarization pixels) having wire grid polarizers has been proposed, the imaging device having a simple configuration and structure and capable of imaging a subject as a stereoscopic image (see PTL 1).

### CITATION LIST

### Patent Literature

### [PTL 1]

JP 2012-230341A

### SUMMARY

### Technical Problem

However, in the technology proposed in PTL 1, there is a concern that a further improvement in polarization efficiency may not be achieved.

Consequently, the present technology has been made in view of such circumstances, and the main object thereof is to provide a solid-state imaging device capable of achieving a further improvement in polarization efficiency, and electronic equipment equipped with the solid-state imaging device.

### Solution to Problem

As a result of earnest research in order to solve the above-described object, the inventor succeeded in further improving the polarization efficiency of the solid-state imaging device and completed the present technology.

That is, according to a first aspect of the present technology, provided is a solid-state imaging device including
a pixel array unit configured such that a plurality of pixels are arranged two-dimensionally,
in which each of the plurality of pixels includes at least a polarizer containing a conductive light shielding material, a photoelectric conversion element that performs photoelectric conversion, and a medium,
the medium is disposed around the polarizer, and
the medium has a predetermined refractive index n.

In the solid-state imaging device according to the first aspect of the present technology,
the refractive index n may be determined as a refractive index nd in accordance with a wavelength targeted by the polarizer, and the medium having the determined refractive index nd may be formed.

In the solid-state imaging device according to the first aspect of the present technology,
the refractive index n may increase as the wavelength targeted by the polarizer increases.

In the solid-state imaging device according to the first aspect of the present technology,
the polarizer may include a wire grid made of the conductive light shielding material, and the refractive index n may satisfy the following Formula (1).

λ1(2×P)≤n≤λ2/(2×P) (1)

(In Formula (1), λ1 is a lower limit wavelength in a range of the wavelength targeted by the polarizer, λ2 is an upper limit wavelength in a range of the wavelength targeted by the polarizer, and λ1 and λ2 are different from each other. Note that λ1 and λ2 may be the same, and the wavelength targeted by the polarizer may be λ1 or λ2. P indicates a pitch of the wire grid.)

In the solid-state imaging device according to the first aspect of the present technology,
λ1 and λ2 in each of at least two of the pixels among the plurality of pixels may be different from each other.

In the solid-state imaging device according to the first aspect of the present technology,
the polarizer may have a structure for generating light having at least two types of polarization states.

In the solid-state imaging device according to the first aspect of the present technology,
the photoelectric conversion element may include an inorganic photoelectric conversion film.

In the solid-state imaging device according to the first aspect of the present technology,
the photoelectric conversion element may include an organic photoelectric conversion film.

In the solid-state imaging device according to the first aspect of the present technology,
the pixel may include the polarizer and the photoelectric conversion element in order from a light incident side.

In the solid-state imaging device according to the first aspect of the present technology,
at least a portion of the photoelectric conversion element may be the medium, and
the polarizer may be formed on a back surface of the photoelectric conversion element on a light incident side.

In the solid-state imaging device according to the first aspect of the present technology,
at least a portion of the photoelectric conversion element may be the medium, and
the polarizer may be formed to be embedded in the photoelectric conversion element.

In the solid-state imaging device according to the first aspect of the present technology,
at least a portion of the photoelectric conversion element may be the medium, the polarizer may be formed on a back surface of the photoelectric conversion element on a light incident side, and
the polarizer may be formed on a front surface of the photoelectric conversion element on a side opposite to the light incident side.

In addition, according to a second aspect of the present technology, provided is a solid-state imaging device including
a pixel array unit configured such that a plurality of first pixels and at least one second pixel are arranged two-dimensionally,
in which each of the plurality of first pixels includes a photoelectric conversion element that performs photoelectric conversion,
the at least one second pixel includes a polarizer containing a conductive light shielding material, a photoelectric conversion element that performs photoelectric conversion, and a medium,
a medium is disposed around the polarizer, and
the medium has a predetermined refractive index n.

In the solid-state imaging device according to the second aspect of the present technology,
the refractive index n may be determined as a refractive index nd in accordance
with a wavelength targeted by the polarizer, and the medium having the determined refractive index nd may be formed.

In the solid-state imaging device according to the second aspect of the present technology,
the predetermined refractive index n may increase as the wavelength targeted by
the polarizer increases.

In the solid-state imaging device according to the second aspect of the present technology,
the polarizer may include a wire grid made of the conductive light shielding material, and
the refractive index n may satisfy the following Formula (1).

λ1(2×P)≤n≤λ2/(2×P) (1)

(In Formula (1), λ1 is a lower limit wavelength in a range of the wavelength targeted by the polarizer, λ2 is an upper limit wavelength in a range of the wavelength targeted by the polarizer, and λ1 and λ2 are different from each other. Note that λ1 and λ2 may be the same, and the wavelength targeted by the polarizer may be Xl or λ2. P indicates a pitch of the wire grid.)

In the solid-state imaging device according to the second aspect of the present technology,
the at least one second pixel may be constituted by a plurality of second pixels, and
λ1 and λ2 in each of at least two of the second pixels among the plurality of second pixels may be different from each other.

In the solid-state imaging device according to the second aspect of the present technology,
the polarizer may have a structure for generating light having at least two types of polarization states.

In the solid-state imaging device according to the second aspect of the present technology,
the photoelectric conversion element may include an inorganic photoelectric conversion film.

In the solid-state imaging device according to the second aspect of the present technology,
the photoelectric conversion element may include an organic photoelectric conversion film.

In the solid-state imaging device according to the second aspect of the present technology,
the at least one second pixel may include the polarizer and the photoelectric conversion element in order from a light incident side.

In the solid-state imaging device according to the second aspect of the present technology,
at least a portion of the photoelectric conversion element may be the medium, and
the polarizer may be formed on a back surface of the photoelectric conversion element on a light incident side.

In the solid-state imaging device according to the second aspect of the present technology,
at least a portion of the photoelectric conversion element may be the medium, and
the polarizer may be formed to be embedded in the photoelectric conversion element.

In the solid-state imaging device according to the second aspect of the present technology,
at least a portion of the photoelectric conversion element may be the medium, the polarizer may be formed on a back surface of the photoelectric conversion element on a light incident side, and
the polarizer may be formed on a front surface of the photoelectric conversion element on a side opposite to the light incident side.

Further, the present technology provides electronic equipment on which the solid-state imaging device according to the first aspect of the present technology or the solid-state imaging device according to the second aspect of the present technology is mounted.

According to the present technology, it is possible to achieve a further improvement in polarization efficiency. Note that the effects described here are not necessarily limited and may be any of the effects described in the present disclosure.

### BRIEF DESCRIPTION OF DRAWINGS

FIG. 1 is a diagram illustrating a configuration example of a solid-state imaging device according to a first embodiment to which the present technology is applied.

FIG. 2 is a diagram illustrating a configuration example of a solid-state imaging device according to a second embodiment to which the present technology is applied.

FIG. 3 is a diagram illustrating a configuration example of a solid-state imaging device according to a third embodiment to which the present technology is applied.

FIG. 4 is a diagram illustrating a configuration example of a solid-state imaging device according to a fourth embodiment to which the present technology is applied.

FIG. 5 is a diagram illustrating a configuration example of a solid-state imaging device according to a fifth embodiment to which the present technology is applied.

FIG. 6 is a diagram illustrating a configuration example of a solid-state imaging device according to a sixth embodiment to which the present technology is applied.

FIG. 7 is a plan view illustrating a configuration example of a solid-state imaging device according to a seventh embodiment to which the present technology is applied.

FIG. 8 is a cross-sectional view illustrating a configuration example of the solid-state imaging device according to the seventh embodiment to which the present technology is applied.

FIG. 9 is a plan view illustrating a configuration example of a solid-state imaging device according to an eighth embodiment to which the present technology is applied.

FIG. 10 is a cross-sectional view illustrating a configuration example of the solid-state imaging device according to the eighth embodiment to which the present technology is applied.

FIG. 11 is a diagram illustrating a configuration example of a wire grid included in a solid-state imaging device to which the present technology is applied.

FIG. 12 is a diagram illustrating a configuration example of wires included in a solid-state imaging device to which the present technology is applied.

FIG. 13 is a diagram illustrating results of an extinction ratio.

FIG. 14 is a diagram illustrating results of an extinction ratio.

FIG. 15 is a diagram illustrating the overall configuration of a solid-state imaging device to which the present technology is applied.

FIG. 16 is a diagram illustrating an example of a cross-sectional configuration of a solid-state imaging device to which the present technology is applied.

FIG. 17 is a diagram illustrating another example of a cross-sectional configuration of a solid-state imaging device to which the present technology is applied.

FIG. 18 is a diagram illustrating still another example of a cross-sectional configuration of a solid-state imaging device to which the present technology is applied.

FIG. 19 is a diagram illustrating examples of use of the solid-state imaging devices according to the first to eighth embodiments to which the present technology is applied.

FIG. 20 is a functional block diagram of an example of electronic equipment according to a ninth embodiment to which the present technology is applied.

FIG. 21 is a diagram illustrating an example of a schematic configuration of an endoscopic surgery system.

FIG. 22 is a block diagram illustrating an example of a functional configuration of a camera head and a CCU.

FIG. 23 is a block diagram illustrating an example of a schematic configuration of a vehicle control system.

FIG. 24 is an illustrative diagram illustrating an example of installation positions of a vehicle exterior information detection unit and an imaging unit.

### DESCRIPTION OF EMBODIMENTS

An outline of the present technology will be described below, followed by a description of a preferred embodiment for implementing the present technology. The embodiments which will be described below show an example of a representative embodiment of the present technology, and the scope of the present technology should not be narrowly interpreted on the basis of this. In the drawings, unless otherwise specified, “up” means the upward direction or toward the upper side in the drawing, “down” means the downward direction or the lower side in the drawing, “left” means the left direction or the left side in the drawing, and “right” means the right direction or the right side in the drawing. Further, in the drawings, the same or equivalent elements or members are denoted by the same reference numerals and signs, and repeated description will be omitted.

Description will be given in the following order.

1. Outline of present technology

2. First embodiment (Example 1 of solid-state imaging device)

3. Second embodiment (Example 2 of solid-state imaging device)

4. Third embodiment (Example 3 of solid-state imaging device)

5. Fourth embodiment (Example 4 of solid-state imaging device)

6. Fifth embodiment (Example 5 of solid-state imaging device)

7. Sixth embodiment (Example 6 of solid-state imaging device)

8. Seventh embodiment (Example 7 of solid-state imaging device)

9. Eighth embodiment (Example 8 of solid-state imaging device)

10. Ninth Embodiment (Example of electronic equipment)

11. Example of use of solid-state imaging device to which the present technology is applied

12. Example of application to endoscopic surgery system

13. Example of application to moving body

### 1. Outline of Present Technology

First, an outline of the present technology will be described. The present technology relates to a solid-state imaging device and electronic equipment equipped with the solid-state imaging device. According to the present technology, a further improvement in polarization efficiency is achieved, and particularly, an extinction ratio can be improved.

An example of another technology other than the present technology will be described.

As an example of another technology, there is technology related to an imaging device including an imaging element array. In the imaging element array, imaging elements are arranged in a two-dimensional matrix, polarization means is provided on a light incident side of a photoelectric conversion element, and light condensed by a lens system is converted into an electrical signal. In the example of the technology, the imaging element is configured such that a color filter, an on-chip lens, and a wire grid polarizer are laminated, and the wire grid polarizer has two structures with different polarization states.

Regarding the wire grid polarizer, there are four desirable points below. Note that examples of the material of a wire constituting the wire grid polarizer include aluminum, an aluminum alloy, and the like.
The height of the wire is 5×10⁻⁸ m (50 nm) or more.
The value of the wire (width/pitch) is 0.33 or more.
The number of wires is 10 or more.
The length of the wire is 2 μm or more, preferably 3 μm or more.

Among the four desirable points related to the wire grid polarizer described above, for example, it is noted that (the width/pitch of) the wire has a value of 0.33 or more. However, as a wavelength becomes longer, it may be difficult to further increase polarization efficiency of the solid-state imaging device (actual device) even when the value (of the width/pitch) of the wires is 0.33 or more.

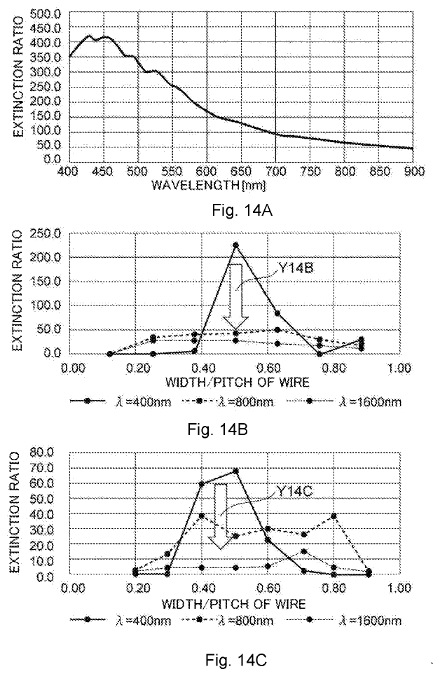

In an example of another technology, for example, examination is performed in a state where the wire is continuously repeated indefinitely without considering a pixel size, and the longer a wavelength, the better an extinction ratio. However, since the actual pixel size in a solid-state imaging device (actual device) is finite, when the pixel size is fixed, the length of the wire, the number of repeated wires, and the like are limited. Thus, when the wavelength of incident light is increased, an extinction ratio is attenuated as illustrated in FIG. 14.

FIG. 14 is a diagram illustrating results of an extinction ratio. Specifically, FIG. 14A is a graph showing results of an extinction ratio (vertical axis) with respect to a wavelength (nm) (horizontal axis). FIG. 14B is a graph showing results of an extinction ratio (vertical axis) with respect to (the width/pitch of) the wire (horizontal axis) when a wavelength λ=400 nm, a wavelength λ=800 nm, and a wavelength λ=1600 nm in a case where the size of a pixel is 1.6 μm (1.6 μm is the length of one side when the pixel is regarded as a square when viewed in a plan view). FIG. 14C is a graph showing results of an extinction ratio (vertical axis) with respect to (the width/pitch of) the wire (horizontal axis) when a wavelength λ=400 nm, a wavelength λ=800 nm, and a wavelength λ=1600 nm in a case where the size of a pixel is 1.0 μm (1.0 μm is the length of one side when the pixel is regarded as a square when viewed in a plan view).

As illustrated in FIG. 14A, the extinction ratio decreases as the wavelength λ (nm) increases. As illustrated in FIG. 14B, the extinction ratio decreases in the order of the wavelength λ=400 nm, the wavelength λ=800 nm, and the wavelength λ=1600 nm as indicated by an arrow Y14B in FIG. 14B in the range of (the width/pitch of) the wire=approximately 0.40 to approximately 0.65. As illustrated in FIG. 14C, the extinction ratio decreases in the order of the wavelength λ=400 nm, the wavelength λ=800 nm, and the wavelength λ=1600 nm as indicated by an arrow Y14C in FIG. 14C in the range of (the width/pitch of) the wire=approximately 0.35 to approximately 0.55.

As described above, it has been confirmed from FIG. 14 (FIGS. 14A to 14C) that the extinction ratios are attenuated as the wavelength of incident light increases.

The present technology is contrived in view of the above-described circumstances. A solid-state imaging device according to a first aspect of the present technology is a solid-state imaging device including a pixel array unit in which a plurality of pixels are arranged two-dimensionally, in which each of the plurality of pixels includes at least a polarizer containing a conductive light shielding material, a photoelectric conversion element that performs photoelectric conversion, and a medium, the medium is disposed around the polarizer, and the medium has a predetermined refractive index n. Further, a solid-state imaging device according to a second aspect of the present technology is a solid-state imaging device including a pixel array unit in which a plurality of first pixels and at least one second pixel are arranged two-dimensionally, in which each of the plurality of first pixels includes a photoelectric conversion element that performs photoelectric conversion, at least one second pixel includes a polarizer containing a conductive light shielding material, a photoelectric conversion element that performs photoelectric conversion, and a medium, the medium is disposed around the polarizer, and the medium has a predetermined refractive index n.

Further, in the solid-state imaging device according to the first or second aspect of the present technology, the polarizer containing the conductive light shielding material, the medium disposed around the polarizer, and the photoelectric conversion element may be disposed in order from a light incident side. In addition, the polarizer containing the conductive light shielding material and the medium disposed around the polarizer may be disposed on a back surface side of the photoelectric conversion element, which is a light incident side, may be disposed on the back surface side of the photoelectric conversion element, which is a light incident side, and a front surface side of the photoelectric conversion element opposite to the light incident side, or may be formed to be embedded in the photoelectric conversion element.

In the solid-state imaging device according to the first or second aspect of the present technology, the predetermined refractive index n may be determined as a refractive index nd in accordance with a wavelength targeted by the polarizer, and the medium having the determined refractive index nd may be formed. In addition, the refractive index n may increase as the wavelength targeted by the polarizer increases. The medium may be formed as a new medium layer, may be formed as at least a portion of the photoelectric conversion element, may be formed as at least a portion of an insulating layer, or may be formed as at least a portion of a planarization layer, depending on the wavelength targeted by the polarizer. Note that, as the photoelectric conversion element, an inorganic photoelectric conversion film and/or an organic photoelectric conversion film can be selected according to the wavelength targeted by the polarizer.

In the solid-state imaging device according to the first or second aspect of the present technology, the polarizer has a wire grid made of a conductive light shielding material, and the refractive index n may satisfy the following Formula (1).

λ1/(2×P)≤n≤λ2/(2×P) (1)

In the Formula (1), λ1 is a lower limit wavelength in the range of the wavelength targeted by the polarizer, λ2 is an upper limit wavelength in the range of the wavelength targeted by the polarizer, and λ1 and λ2 are different from each other. Note that λ1 and the λ2 may be the same, and the wavelength targeted by the polarizer may be λ1 or λ2. P indicates the pitch of the wire grid.

FIG. 11 is a cross-sectional view illustrating a configuration of a polarizer 10 (hereinafter referred to as a wire grid polarizer 10) having a wire grid made of a conductive light shielding material (wires 11).

As illustrated in FIG. 11, the wire grid polarizer 10 is formed such that a plurality of wires 11 are arranged at intervals of a pitch P in the x-axis direction (a length which is parallel in the x-axis direction from a left side of a left wire 11 to a left side of a right wire 11 in two adjacent wires 11). In addition, a medium 1 having a predetermined refractive index n is disposed around the wire grid polarizer 10.

According to the solid-state imaging device of the present technology, as illustrated in FIG. 11, the pitch P and an effective wavelength of incident light (light L) (the incident light (light L)/the refractive index n of the medium 1) are controlled, and thus it is possible to improve an extinction ratio in a long wavelength range, which has been difficult in the related art, and to improve an extinction ratio of a solid-state imaging device (for example, a polarization sensor) targeting a specific wavelength.

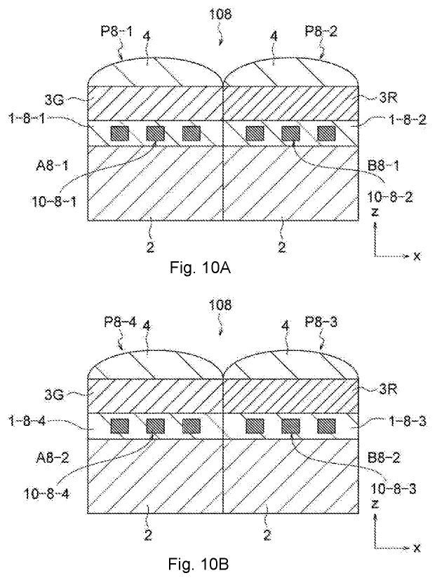

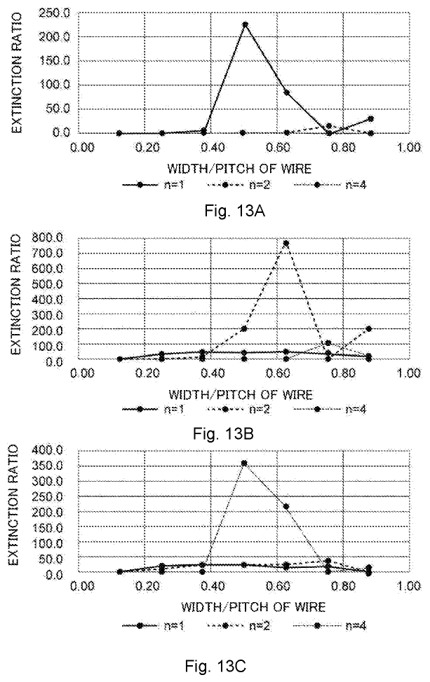

FIG. 12 is a cross-sectional view illustrating the configuration of the wire 11. As illustrated in FIG. 12, in the wire 11, a length in the z-axis direction (the height of the wire) is a (nm), and a length in the x-axis direction (the width of the wire) is b (nm). A material forming the wire 11 may be, for example, aluminum (λ1). In results of extinction ratio illustrated in FIG. 13, which will be described later, a is 300 nm, and b is 100 nm.

FIG. 13 is a diagram illustrating results of an extinction ratio. Specifically, FIG. 13A is a graph showing results of an extinction ratio (vertical axis) with respect to (the width/pitch of) the wire (horizontal axis) when the refractive index n of the medium is 1 (refractive index n=1), 2 (refractive index n=2), and 4 (refractive index n=4) in a case where the size of a pixel is 1.6 μm (1.6 μm is the length of one side when the pixel is regarded as a square when viewed in a plan view), and the wavelength λ=400 nm (visible region). FIG. 13B is a graph showing results of an extinction ratio (vertical axis) with respect to (the width/pitch of) the wire (horizontal axis) when the refractive index n of the medium is 1 (refractive index n=1), 2 (refractive index n=2), and 4 (refractive index n=4) in a case where the size of a pixel is 1.6 μm (1.6 μm is the length of one side when the pixel is regarded as a square when viewed in a plan view), and the wavelength λ=800 nm (NIR region). FIG. 13C is a graph showing results of an extinction ratio (vertical axis) with respect to (the width/pitch of) the wire (horizontal axis) when the refractive index n of the medium is 1 (refractive index n=1), 2 (refractive index n=2), and 4 (refractive index n=4) in a case where the size of a pixel is 1.6 μm (1.6 μm is the length of one side when the pixel is regarded as a square when viewed in a plan view), and the wavelength λ=1600 nm (IR region).

As illustrated in FIG. 13A, in the visible region (wavelength λ=400), the refractive index n of the medium being 1 (refractive index n=1) results in the highest extinction ratio in the range of (the width/pitch of) the wire from approximately 0.40 to approximately 0.70. An effective wavelength (wavelength λ/refractive index n) is 400 nm (400 nm/1).

As illustrated in FIG. 13B, in the NIR region (wavelength λ=800), the refractive index n of the medium being 2 (refractive index n=2) results in the highest extinction ratio in the range of (the width/pitch of) the wire from approximately 0.40 to approximately 0.70. An effective wavelength (wavelength λ/refractive index n) is 400 nm (800 nm/2).

As illustrated in FIG. 13C, in the NIR region (wavelength λ=800), the refractive index n of the medium being 4 (refractive index n=4) results in the highest extinction ratio in the range of (the width/pitch of) the wire from approximately 0.40 to approximately 0.70. An effective wavelength (wavelength λ/refractive index n) is 400 nm (1600 nm/4).

As described above, from FIG. 13 (FIGS. 13A to 13C), it is confirmed that the predetermined refractive index n (n=1→n=4) increases as the target wavelength increases (400 nm→1600 nm). From the results illustrated in FIG. 13 (FIGS. 13A to 13C), the extinction ratio is the highest when an effective wavelength is 400 nm as described above.

Next, the overall configuration of the solid-state imaging device according to the present technology (for example, a complementary metal oxide semiconductor (CMOS) type solid-state imaging device) will be described with reference to FIG. 15, and an example of a cross-sectional configuration of the solid-state imaging device according to the present technology (for example, a complementary metal oxide semiconductor (CMOS) type solid-state imaging device) will be described with reference to FIGS. 16 to 18.

As illustrated in FIG. 15, a solid-state imaging device 1M according to the present technology is configured to include a pixel region 3M having a plurality of pixels 2M arranged on a substrate 11M made of silicon, a vertical drive circuit 4M, and column signal processing circuits 5M, a horizontal drive circuit 6M, an output circuit 7M, a control circuit 8M, and the like.

The pixel 2M is constituted by, for example, a photoelectric conversion unit made of a photodiode and a plurality of pixel transistors, and the plurality of pixels 2M are regularly arranged in a two-dimensional array on the substrate 11M. The pixel transistors constituting the pixel 2M may be four MOS transistors constituted by a transfer transistor, a reset transistor, a selection transistor, and an amplification transistor, or may be three transistors excluding the selection transistor.

The pixel region 3M has the plurality of pixels 2M regularly arranged in a two-dimensional array. The pixel region 3M is constituted by an effective pixel region for actually receiving light, amplifying signal charge generated by photoelectric conversion, and reading the signal charge to the column signal processing circuits 5M, and a black reference pixel region (not illustrated) for outputting an optical black as a reference for a black level. The black reference pixel region is generally formed on the outer peripheral portion of the effective pixel region.

The control circuit 8M generates a clock signal, a control signal, and the like as a reference for operations of the vertical drive circuit 4M, the column signal processing circuits 5M, the horizontal drive circuit 6M, and the like based on a vertical synchronization signal, a horizontal synchronization signal, and a master clock. Then, the clock signal, the control signal, and the like generated by the control circuit 8M are input to the vertical drive circuit 4M, the column signal processing circuits 5M, the horizontal drive circuit 6M, and the like.

The vertical drive circuit 4M is constituted by, for example, a shift register, and sequentially selects and scans the pixels 2M in the pixel region 3M in units of rows in the vertical direction. In addition, a pixel signal based on the signal charge generated in the photodiode of each of the pixels 2M in accordance with the amount of received light is supplied to the column signal processing circuit 5M through a vertical signal line.

The column signal processing circuit 5M is disposed, for example, for each column of the pixels 2M, and performs signal processing such as noise removal and signal amplification on signals output from the pixels 2M corresponding to one row by using signals from the black reference pixel region (which is not illustrated in the drawing, but is formed in the vicinity of the effective pixel region) for each pixel column. A horizontal selection switch (not illustrated) is provided between an output stage of the column signal processing circuit 5M and a horizontal signal line 10M.

The horizontal drive circuit 6M is constituted by, for example, a shift register, and sequentially outputs horizontal scanning pulses and thus selects each of the column signal processing circuits 5 in order, and outputs a pixel signal from each of the column signal processing circuits 5 to the horizontal signal line 10M.

The output circuit 7M performs signal processing on signals sequentially supplied from each of the column signal processing circuits 5M through the horizontal signal line 10M and outputs the signals.

Description will be made with reference to FIG. 16. FIG. 16 illustrates a cross-sectional configuration of the pixel region 3M of the solid-state imaging device 1M according to the present technology.

The solid-state imaging device 1M is an example of a back-illuminated CMOS type solid-state imaging device. The solid-state imaging device 1M can have, for example, a so-called 4-pixel sharing unit in which required pixel transistors are shared by four photoelectric conversion units. In the following description, it is assumed that a first conductivity type is a p-type and a second conductivity type is an n-type.

As illustrated in FIG. 16, the solid-state imaging device 1M includes a substrate 12M including a plurality of pixels, a wiring layer 13M formed on the front surface side (the lower side in FIG. 16) of the substrate 12M, and a support substrate 31M. In addition, the solid-state imaging device 1M further includes an insulating film (hereinafter referred to as a fixed charge film) 20M having fixed charge, an insulating film 21M, a light shielding film 25M, a planarization film 26M, a color filter 27M, and an on-chip lens 28M that are formed in order on the back surface side (the upper side in FIG. 16) of the substrate 12M.

The substrate 12M is constituted by a semiconductor substrate made of silicon and is formed to have a thickness of, for example, 1 μm to 6 μm. In the pixel region 3M of the substrate 12M, pixels including, for example, a photoelectric conversion unit 40M constituted by a photodiode and a pixel transistor Tr1 constituting a pixel circuit unit are formed. In addition, adjacent photoelectric conversion units 40M are electrically isolated by an element isolation portion 19M. Further, although not illustrated in FIG. 16, a peripheral circuit unit is formed in a peripheral region of the pixel region formed in the substrate 12M.

The photoelectric conversion unit 40M is constituted by first conductivity type (hereinafter p-type) semiconductor regions 23M and 24M formed on the front surface side (the lower side in FIG. 16) and the back surface side (the upper side in FIG. 16) of the substrate 12M, and a second conductivity type (hereinafter referred to as an n-type) semiconductor region 22M formed therebetween. In the photoelectric conversion unit 40M, a main photodiode is provided between the p-type semiconductor regions 23M and 24M and the n-type semiconductor region 22M by a pn junction. In the photoelectric conversion unit 40M, signal charge corresponding to the amount of incident light is generated and accumulated in the n-type semiconductor region 22M. Further, electrons that cause a dark current generated at an interface of the substrate 12M are absorbed into holes that are a large number of carriers of the p-type semiconductor regions 23M and 24M formed on the front surface side (the lower side in FIG. 16) and the back surface (the upper side in FIG. 16) of the substrate 12M, and thus a dark current is suppressed. In addition, each photoelectric conversion unit 40M is electrically isolated by a pixel isolation layer 18M constituted by a p-type semiconductor region and the element isolation portion 19M formed in the pixel isolation layer 18M. As illustrated in FIG. 16, a floating diffusion portion 30M is constituted by an n-type semiconductor region formed by ion-implanting n-type impurities at a high concentration into a p-well layer 29M formed on the front surface side of the substrate 12M. In addition, a transfer gate electrode 16M is formed on the front surface side of the substrate 12M between the photoelectric conversion unit 40M and the floating diffusion portion 30M with a gate insulating film 17M interposed therebetween.

The wiring layer 13M is formed on the front surface side of the substrate 12M, and is configured to include wirings 15M laminated in a plurality of layers (three layers in FIG. 16) through an interlayer insulating film 14M. A pixel transistor Tr that constitutes the pixel 2M is driven through the wirings 15M formed in the wiring layer 13M.

In the solid-state imaging device 1M, all of the pixels of the solid-state imaging device 1M may have a polarizer containing a conductive light shielding material (for example, a polarizer having a wire grid made of a conductive light shielding material) (not illustrated in FIG. 16), and at least one of all of the pixels of the solid-state imaging device 1M may have a polarizer containing a conductive light shielding material (for example, a polarizer having a wire grid made of a conductive light shielding material) (not illustrated in FIG. 16). Note that a pixel having a polarizer containing a conductive light shielding material (for example, a polarizer having a wire grid made of a conductive light shielding material) may be referred to as a polarizing pixel, and a pixel that does not have a polarizer containing a conductive light shielding material (for example, a polarizer having a wire grid made of a conductive light shielding material) may be referred to as a normal pixel (imaging pixel).

In the solid-state imaging device 1M, for example, a polarizer containing a conductive light shielding material (for example, a polarizer having a wire grid made of a conductive light shielding material) (not illustrated), a medium (not illustrated) disposed around the polarizer, and the photoelectric conversion unit 40M may be disposed in order from a light incident side. Further, in the solid-state imaging device 1M, for example, the polarizer containing a conductive light shielding material (for example, a polarizer having a wire grid made of a conductive light shielding material) (not illustrated) may be disposed on the back surface side of the photoelectric conversion unit 40M, may be disposed on the back surface side of the photoelectric conversion unit 40M and the front surface side of the photoelectric conversion unit 40M, or may be formed to be embedded in the photoelectric conversion unit 40M. In these three cases, at least a portion of the photoelectric conversion unit 40M is the medium (not illustrated) disposed around the polarizer. Further, in the solid-state imaging device 1M, for example, the polarizer containing a conductive light shielding material (for example, a polarizer having a wire grid made of a conductive light shielding material) and the medium (not illustrated) disposed around the polarizer may be formed in substantially the same layer (substantially the same height) as the light shielding film 25M.

Description will be made with reference to FIG. 17. FIG. 17 illustrates a cross-sectional configuration of a solid-state imaging device 1F according to the present technology.

The solid-state imaging device 1F is configured such that a support substrate 2F, a wiring portion 3F, a silicon substrate 4F, a color filter 5F, and an on-chip lens 6F are formed from the front surface side thereof (from the upper side in FIG. 17). The wiring portion 3F is configured such that a plurality of wiring layers 12F are formed through an interlayer insulating layer 11F. A thin insulating film 13F serving as a gate insulating film is formed between the wiring portion 3F and the silicon substrate 4F, and a gate electrode 14F for reading charge is formed on the front surface side of this insulating film 13F. In the silicon substrate 4F, an N-type region 17F constituting a photodiode of a light receiving sensor unit is formed thick in the thickness direction, and a positive charge storage region (P+ region) 16F is formed on the front surface side of the N-type region 17F. In addition, an N-type floating diffusion (FD) 15F is formed through a read region under the gate electrode 14F. Although not illustrated in the drawing, the support substrate 2F and the wiring portion 3F are adhered to each other by an adhesive layer or the like. As the support substrate 2F, for example, a silicon substrate can be used. As the support substrate 2F, a substrate made of another material may be used as long as the material has good flatness and a small difference in a coefficient of thermal expansion from that of silicon. In addition, the support substrate 2F is configured such that light L is incident from the lens 6F side, that is, the back surface side opposite to the wiring portion 3F, and a so-called back-illuminated CMOS sensor is configured.

A read transistor is constituted by the gate electrode 14F, the tip of the N-type region 17F, and the floating diffusion 15F. Further, in a cross-section not illustrated in the drawing, other transistors in a pixel and a circuit element of a peripheral portion are formed in a portion on the front surface side of the silicon substrate 4.

For example, a thickness D of the silicon layer (silicon substrate) 4F on which the light receiving sensor unit is formed is set to 10 μm or less. More preferably, the thickness D of the silicon layer 4F is set to 5 μm or less. Thereby, since the silicon layer 4F is formed to have a small thickness D, it is possible to suppress the occurrence of color mixing due to the incidence of light on adjacent pixels and realize high sensitivity. Further, a drift electric field of approximately 200 mV/μm or more can be formed by making a design in the range of a drive voltage (2.5 V to 3.3 V) normally used in CMOS sensors, and thus it is possible to reliably perform reading of charge to the front surface side by the electric field. In addition, noise caused by light irradiation is also equal to or lower than that of a CMOS type solid-state imaging device having a surface irradiation type structure.

For example, when the thickness D of the silicon layer 4F is set to 10 μm or less, a high sensitivity is obtained in a wide wavelength range including an infrared region.

For example, when the thickness D of the silicon layer 4F is set to 5 μm or less, a high sensitivity can be obtained in a visible light region. In addition, since a drift electric field of approximately 400 mV/μm or more can be formed when a design is made within the range of the drive voltage described above, it is possible to easily read charge to the front surface side.

For example, when the thickness D of the silicon layer 4F is set to 5 μm or less, there is an advantage of facilitating manufacturing. For example, when the thickness D of the silicon layer 4F exceeds 5 μm, it is necessary to perform ion implantation with very high energy or form a hard mask such as an oxide film before the ion implantation in order to form the N-type region 17F. On the other hand, for example, when the thickness D of the silicon layer 4F is set to 5 μm or less, ion implantation for forming the N-type region 17F can be performed using a resist mask, and thus manufacturing can be facilitated.

Further, in the solid-state imaging device 1F, a P+ region (high-concentration P-type region) 18F is formed over the entire depth direction as a pixel isolation region between the N-type regions 17F of the light receiving sensor units of the adjacent pixels. Thereby, the N-type regions 17F of the pixels can be electrically isolated from each other to prevent electrical color mixing between the adjacent pixels.

Further, in the solid-state imaging device 1F, a P+ region 19F is also formed on the back surface side (the lower side in FIG. 17) of the N-type region 17F, that is, on the color filter 5F side. Thereby, a dark current caused by an interface level on the back surface side of the silicon layer 4F can also be reduced.

In the solid-state imaging device 1F, all of pixels of the solid-state imaging device 1F may have a polarizer containing a conductive light shielding material (for example, a polarizer having a wire grid made of a conductive light shielding material) (not illustrated in FIG. 17), and at least one of all of the pixels of the solid-state imaging device 1F may have a polarizer containing a conductive light shielding material (for example, a polarizer having a wire grid made of a conductive light shielding material) (not illustrated in FIG. 17). Note that a pixel having a polarizer containing a conductive light shielding material (for example, a polarizer having a wire grid made of a conductive light shielding material) may be referred to as a polarizing pixel, and a pixel that does not have a polarizer containing a conductive light shielding material (for example, a polarizer having a wire grid made of a conductive light shielding material) may be referred to as a normal pixel (imaging pixel).

In the solid-state imaging device 1F, for example, a polarizer containing a conductive light shielding material (for example, a polarizer having a wire grid made of a conductive light shielding material), a medium (not illustrated) disposed around the polarizer, and the silicon layer 4F may be disposed in order from a light incident side. Further, in the solid-state imaging device 1F, for example, the polarizer containing a conductive light shielding material may be disposed on the back surface side of the silicon layer 4F, may be disposed on the back surface side of the silicon layer 4F and the front surface side of the silicon layer 4F, or may be formed to be embedded in the silicon layer 4F. In these three cases, at least a portion of the silicon layer 4F is the medium (not illustrated) disposed around the polarizer.

Description will be made with reference to FIG. 18. FIG. 18 illustrates a cross-sectional configuration of a solid-state imaging device 211G according to the present technology.

The solid-state imaging device 211G is configured such that a photodiode PD (photoelectric conversion element) constituted by a charge accumulation region 53G of a first conductivity type, for example, an n-type formed on a main surface of a semiconductor substrate 100G and a p-type semiconductor region (p-type accumulation layer) 54G of a second conductivity type formed on the front surface thereof is formed, and a plurality of MOS transistors are formed.

FIG. 18 illustrates a transfer transistor Tr1 and a reset transistor Tr2 among the plurality of MOS transistors. The transfer transistor Tr1 is constituted by an n-type semiconductor region 55G serving as a floating diffusion portion FD, a photodiode PD, and a transfer gate electrode 56G formed through a gate insulating film. The reset transistor Tr2 is constituted by the n-type semiconductor region 55G serving as the floating diffusion portion FD, an n-type semiconductor region 57G, and a reset gate electrode 58G formed through a gate insulating film. A unit pixel 60G is isolated from adjacent pixels by an element isolation region 59G.

A so-called multilayer wiring layer 63G is formed on the semiconductor substrate 100G on which the pixels are formed, the multilayer wiring layer 63G being configured such that wirings 621, 622G, and 623G of a plurality of layers, that is, three metal layers in FIG. 18 are formed through an interlayer insulating film 61G. The multilayer wiring layer 63G is formed except for a region corresponding to the photodiode PD. A color filter 66G is formed on the multilayer wiring layer 63G via a planarization film 65G, and an on-chip microlens 68G is formed thereon via a planarization film 67G.

In addition, the interlayer insulating film 61G in the multilayer wiring layer 63G is formed by a light shielding interlayer insulating film except on the photodiode PD. That is, the interlayer insulating film 61G between the wiring 621G and the wiring 622G and between the wiring 622G and the wiring 623G, more specifically, the entire interlayer insulating film 61G including portions between the mutual wirings is formed by a light shielding insulating film. That is, the wirings 621G, 622G, and 623G are formed to be embedded in the light shielding interlayer insulating film 61G. The wiring 623G which is the uppermost layer may also serve as a light shielding metal.

The interlayer insulating film 61G is formed of a material that is less likely to transmit visible light, instead of a light-transmissive SiO₂ film or SiN film. For example, the entire interlayer insulating film 61G can be formed by an insulating film made of a material such as SiC, SiOC, amorphous carbon (a-C), or a pigment-containing organic material (for example, polyimide).

On the other hand, an insulating film 69G in a region corresponding to the photodiode PD is formed by a light-transmissive insulating film, that is, a silicon oxide (SiO₂) film, a silicon nitride (SiN) film, or an organic material which transmits visible light. The above-described interlayer insulating film 61G having a light shielding property can also be formed on peripheral circuits (a vertical drive circuit, a column signal processing circuit, a horizontal drive circuit, an output circuit, a control circuit, and the like, which are not illustrated in FIG. 18) at the same time.

According to the solid-state imaging device 211G, the entire interlayer insulating film 61G in the multilayer wiring layer 63G is formed by a light shielding insulating film, and thus it is possible to sufficiently obtain a thickness as a light shielding layer and to improve a light shielding capability. The light shielding insulating film itself absorbs light, and thus can have a light shielding function. For this reason, light can be shielded regardless of an incident angle of incident light. For example, since the wiring 623G which is the uppermost layer can also serve as a light shielding metal, the wiring 623G can further improve a light shielding ability together with the light shielding metal 623G. Thus, the MOS transistor in the pixel or the peripheral circuits are more reliably shielded from light, and malfunction and disturbance of an output image can be avoided. Further, since the light shielding interlayer insulating film 61G is formed between the wirings, leakage of light between the wirings is prevented, and light does not leak into adjacent pixels through the wirings, thereby making it possible to reduce color mixing.

In the solid-state imaging device 211G, all of pixels of the solid-state imaging device 211G may have a polarizer containing a conductive light shielding material (for example, a polarizer having a wire grid made of a conductive light shielding material) (not illustrated in FIG. 18), and at least one of all of the pixels of the solid-state imaging device 211G may have a polarizer containing a conductive light shielding material (for example, a polarizer having a wire grid made of a conductive light shielding material) (not illustrated in FIG. 18). Note that a pixel having a polarizer containing a conductive light shielding material (for example, a polarizer having a wire grid made of a conductive light shielding material) may be referred to as a polarizing pixel, and a pixel that does not have a polarizer containing a conductive light shielding material (for example, a polarizer having a wire grid made of a conductive light shielding material) may be referred to as a normal pixel (imaging pixel).

In the solid-state imaging device 211F, for example, a polarizer containing a conductive light shielding material (for example, a polarizer having a wire grid made of a conductive light shielding material) (not illustrated), a medium (not illustrated) disposed around the polarizer, and the photodiode PD may be disposed in order from a light incident side. Further, in the solid-state imaging device 211F, for example, the polarizer containing a conductive light shielding material may be disposed on the back surface side of the photodiode PD, may be disposed on the back surface side of the photodiode PD and the front surface side of the photodiode PD, or may be formed to be embedded in the photodiode PD. In these three cases, at least a portion of the photodiode PD is the medium (not illustrated) disposed around the polarizer.

Subsequently, preferred embodiments for implementing the present technology will be described in detail with reference to the drawings.

### 2. First Embodiment (Example 1 of Solid-State Imaging Device)

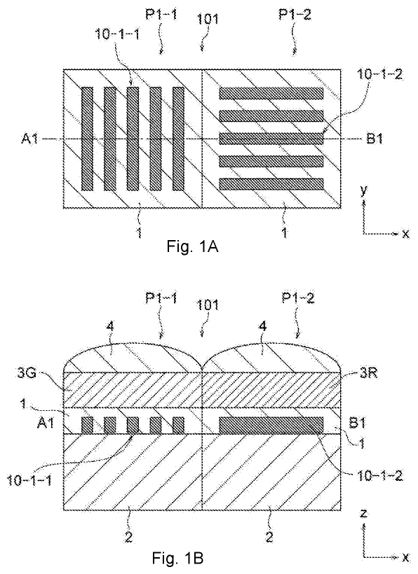

A solid-state imaging device of a first embodiment (Example 1 of a solid-state imaging device) according to the present technology will be described with reference to FIG. 1.

FIG. 1 is a diagram illustrating a solid-state imaging device 101 which is the solid-state imaging device of the first embodiment according to the present technology. Specifically, FIG. 1A is a plan view of two pixels (pixels P1-1 and P1-2) of the solid-state imaging device 101 (a planar layout diagram of two pixels of the solid-state imaging device 101 from a light incident side), and FIG. 1B is a cross-sectional view of two pixels (pixels P1-1 and P1-2) of the solid-state imaging device 101 along line A1-B1 illustrated in FIG. 1A.

As illustrated in FIG. 1A, in the pixel P1-1, a polarizer 10-1-1 having a wire grid made of a conductive light shielding material (hereinafter referred to as a wire grid polarizer 10-1-1) is formed to extend in a direction of approximately 90 degrees (y-axis direction) with respect to the x-axis direction. On the other hand, in the pixel P1-2, a polarizer 10-1-2 having a wire grid made of a conductive light shielding material (hereinafter referred to as a wire grid polarizer 10-1-2) is formed to extend in a direction of approximately 0 degrees (x-axis direction) with respect to the x-axis direction. In addition, the extension direction of the wire grid polarizer 10-1-1 and the extension direction of the polarizer 10-1-2 having a wire grid are orthogonal to each other.

As illustrated in FIG. 1B, in the pixel P1-1, an on-chip lens 4, a color filter 3 (in FIG. 1B, for example, a color filter that transmits green light (green filter) 3G), a medium 1, and a photoelectric conversion element 2 are formed in order from a light incident side (the upper side in FIG. 1B). The wire grid polarizer 10-1-1 is formed in the medium 1. That is, the medium 1 is disposed around the wire grid polarizer 10-1-1.

In the pixel P1-2, the on-chip lens 4, the color filter 3 (in FIG. 1B, for example, a color filter (red filter) 3R that transmits red light), the medium 1, and the photoelectric conversion element 2 are formed in order from a light incident side (the upper side in FIG. 1B). The wire grid polarizer 10-1-2 is formed in the medium 1. That is, the medium 1 is disposed around the wire grid polarizer 10-1-2.

In the solid-state imaging device 101, for example, a medium 1 made of a material (high refractive index material) having a refractive index n higher than a refractive index n of air or an oxide film (for example, an insulating film) can be used. Further, in the solid-state imaging device 101, a medium 1 having a controlled refractive index n can be used depending on a target wavelength λ. According to the solid-state imaging device 101, an extinction ratio in a long wavelength and/or a specific wavelength can be improved by controlling an effective wavelength by the medium 1 having the controlled refractive index n.

The above-described contents of the solid-state imaging device of the first embodiment (Example 1 of a solid-state imaging device) according to the present technology can be applied to solid-state imaging devices according to second to eighth embodiments of the present technology to be described later, unless there is no particular technical contradiction.

### 3. Second Embodiment (Example 2 of Solid-State Imaging Device)

The solid-state imaging device of the second embodiment (Example 2 of a solid-state imaging device) according to the present technology will be described with reference to FIG. 2.

FIG. 2 is a diagram illustrating a solid-state imaging device 102 which is the solid-state imaging device of the second embodiment according to the present technology. Specifically, FIG. 2A is a plan view of two pixels (pixels P2-1 and P2-2) of the solid-state imaging device 102 (a planar layout diagram of two pixels of the solid-state imaging device 102 from a light incident side), and FIG. 2B is a cross-sectional view of two pixels (pixels P2-1 and P2-2) of the solid-state imaging device 102 along line A2-B2 illustrated in FIG. 2A.

As illustrated in FIG. 2A, in the pixel P2-1, a polarizer 10-2-1 having a wire grid made of a conductive light shielding material (hereinafter referred to as a wire grid polarizer 10-2-1) is formed to extend in a direction of approximately 135 degrees with respect to the x-axis direction. That is, the wire grid polarizer 10-2-1 is obtained by tilting the wire grid polarizer 10-1-1 illustrated in FIG. 1 at approximately 45 degrees counterclockwise. On the other hand, in the pixel P2-2, the polarizer 10-2-2 having a wire grid made of a conductive light shielding material (hereinafter referred to as a wire grid polarizer 10-2-2) is formed to extend in a direction of approximately 45 degrees with respect to the x-axis direction. That is, the wire grid polarizer 10-2-2 is obtained by tilting the wire grid polarizer 10-1-2 illustrated in FIG. 1 at approximately 45 degrees counterclockwise. In addition, the extension direction of the wire grid polarizer 10-2-1 and the extension direction of the polarizer 10-2-2 having a wire grid are orthogonal to each other.

As illustrated in FIG. 2B, in the pixel P2-1, an on-chip lens 4, a color filter 3 (in FIG. 2B, for example, a color filter that transmits green light (green filter) 3G), a medium 1, and a photoelectric conversion element 2 are formed in order from a light incident side (the upper side in FIG. 2B). The wire grid polarizer 10-2-1 is formed in the medium 1. That is, the medium 1 is disposed around the wire grid polarizer 10-2-1.

In the pixel P2-2, the on-chip lens 4, the color filter 3 (in FIG. 2B, for example, a color filter (red filter) 3R that transmits red light), the medium 1, and the photoelectric conversion element 2 are formed in order from a light incident side (the upper side in FIG. 2B). The wire grid polarizer 10-2-2 is formed in the medium 1. That is, the medium 1 is disposed around the wire grid polarizer 10-2-2.

In the solid-state imaging device 102, for example, a medium 1 made of a material (high refractive material) having a refractive index n higher than a refractive index n of air or an oxide film (for example, an insulating film) can be used. Further, in the solid-state imaging device 102, a medium 1 having a controlled refractive index n can be used depending on a target wavelength λ. According to the solid-state imaging device 102, an extinction ratio in a long wavelength and/or a specific wavelength can be improved by controlling an effective wavelength by the medium 1 having the controlled refractive index n.

In the solid-state imaging device 102, two wire grid polarizers 10-1-1 to 10-1-2 included in the solid-state imaging device 101 may be respectively disposed in at least two pixels (not illustrated) other than the pixels P2-1 to P2-2. Thereby, in the solid-state imaging device 102, four types of wire grid polarizers having wires extending in directions of approximately 0 degrees, approximately 45 degrees, approximately 90 degrees, and approximately 135 degrees with respect to the x-axis direction can generate light having four types of polarization states.

The above-described contents of the solid-state imaging device of the second embodiment (Example 2 of a solid-state imaging device) according to the present technology can be applied to the above-described solid-state imaging device of the first embodiment according to the present technology and solid-state imaging devices to be described later of third to eighth embodiments according to the present technology, unless there is no particular technical contradiction.

### 4. Third Embodiment (Example 3 of Solid-State Imaging Device)

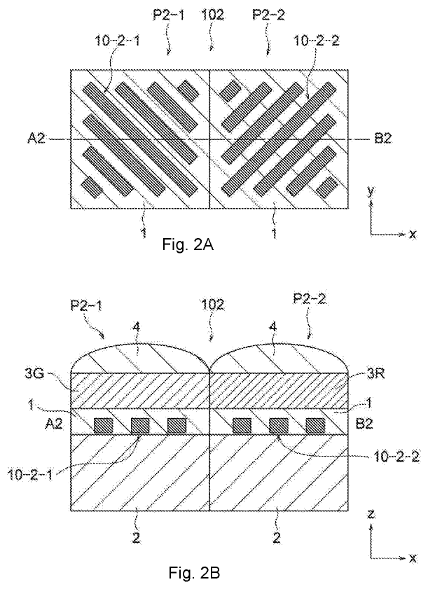

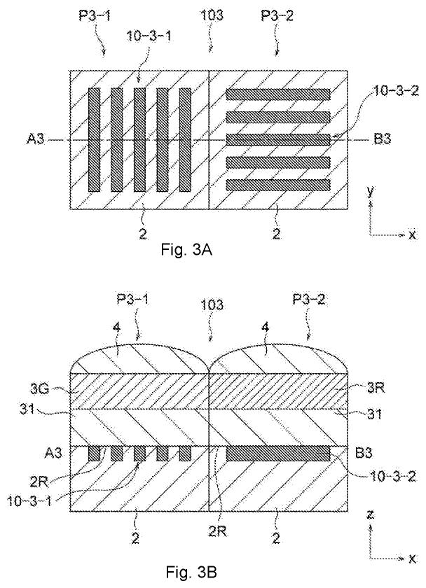

The solid-state imaging device of the third embodiment (Example 3 of the solid-state imaging device) according to the present technology will be described with reference to FIG. 3.

FIG. 3 is a diagram illustrating a solid-state imaging device 103 which is the solid-state imaging device of the third embodiment according to the present technology. Specifically, FIG. 3A is a plan view of two pixels (pixels P3-1 and P3-2) of the solid-state imaging device 103 (a planar layout diagram of two pixels of the solid-state imaging device 103 from a light incident side), and FIG. 3B is a cross-sectional view of two pixels (pixels P3-1 and P3-2) of the solid-state imaging device 103 along line A3-B3 illustrated in FIG. 3A.

As illustrated in FIG. 3A, in the pixel P3-1, a polarizer 10-3-1 having a wire grid made of a conductive light shielding material (hereinafter referred to as a wire grid polarizer 10-3-1) is formed to extend in a direction of approximately 90 degrees (y-axis direction) with respect to the x-axis direction. On the other hand, in the pixel P3-2, a polarizer 10-3-2 having a wire grid made of a conductive light shielding material (hereinafter referred to as a wire grid polarizer 10-3-2) is formed to extend in a direction of approximately 0 degrees (x-axis direction) with respect to the x-axis direction. In addition, the extension direction of the wire grid polarizer 10-3-1 and the extension direction of the polarizer 10-3-2 having a wire grid are orthogonal to each other.

As illustrated in FIG. 3B, in the pixel P3-1, an on-chip lens 4, a color filter 3 (in FIG. 3B, for example, a color filter that transmits green light (green filter) 3G), a wire grid upper film 31, and a photoelectric conversion element 2 are formed in order from a light incident side (the upper side in FIG. 3B). The wire grid polarizer 10-3-1 is formed on a back surface 2R of the photoelectric conversion element 2, which is a light incident side. That is, at least a portion of the photoelectric conversion element 2 on the back surface 2R side of the photoelectric conversion element 2 is a medium, and the medium is disposed around the wire grid polarizer 10-3-1.

As illustrated in FIG. 3B, in the pixel P3-2, the on-chip lens 4, the color filter 3 (in FIG. 3B, for example, a color filter that transmits red light (red filter) 3R), the wire grid upper film 31, and the photoelectric conversion element 2 are formed in order from a light incident side (the upper side in FIG. 3B). The wire grid polarizer 10-3-2 is formed on the back surface 2R of the photoelectric conversion element 2, which is a light incident side. That is, at least a portion of the photoelectric conversion element 2 on the back surface 2R side of the photoelectric conversion element 2 is a medium, and the medium is disposed around the wire grid polarizer 10-3-2.

In the solid-state imaging device 103, when an optimum refractive index n for improving an extinction ratio is substantially the same as the refractive index n of the photoelectric conversion element 2, the wire grid polarizers 10-3-1 and 10-3-2 are formed on a back surface 2R of the photoelectric conversion element 2. It is preferable that a refractive index n of a material forming the wire grid upper film 31 included in the solid-state imaging device 103 be close to or substantially equal to the refractive index n of the photoelectric conversion element 2. The solid-state imaging device 103 has a structure in which an effective wavelength of incident light is modulated by the refractive index of the photoelectric conversion layer, so that the extinction ratio can be improved. Note that the wire grid polarizers 10-3-1 and 10-3-2 are formed not only on the back surface 2R of the photoelectric conversion element 2, but also on the front surface (a side opposite to a light incident side) of the photoelectric conversion element 2.

The above-described contents of the solid-state imaging device of the third embodiment (Example 3 of a solid-state imaging device) according to the present technology can be applied to the above-described solid-state imaging devices of the first and second embodiments according to the present technology and solid-state imaging devices of fourth to eighth embodiments according to the present technology to be described later, unless there is no particular technical contradiction.

### 5. Fourth Embodiment (Example 4 of Solid-State Imaging Device)

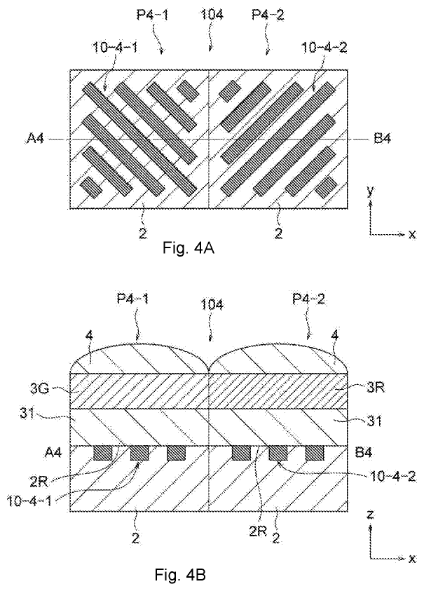

The solid-state imaging device of the fourth embodiment (Example 4 of the solid-state imaging device) according to the present technology will be described with reference to FIG. 4.

FIG. 4 is a diagram illustrating a solid-state imaging device 104 which is the solid-state imaging device of the fourth embodiment according to the present technology. Specifically, FIG. 4A is a plan view of two pixels (pixels P4-1 and P4-2) of the solid-state imaging device 104 (a planar layout diagram of two pixels of the solid-state imaging device 104 from a light incident side), and FIG. 4B is a cross-sectional view of two pixels (pixels P4-1 and P4-2) of the solid-state imaging device 104 along line A4-B4 illustrated in FIG. 4A.

As illustrated in FIG. 4A, in the pixel P4-1, a polarizer 10-4-1 having a wire grid made of a conductive light shielding material (hereinafter referred to as a wire grid polarizer 10-4-1) is formed to extend in a direction of approximately 135 degrees with respect to the x-axis direction. That is, the wire grid polarizer 10-4-1 is obtained by tilting the wire grid polarizer 10-3-1 illustrated in FIG. 3 at approximately 45 degrees counterclockwise. On the other hand, in the pixel P4-2, the polarizer 10-4-2 having a wire grid made of a conductive light shielding material (hereinafter referred to as a wire grid polarizer 10-4-2) is formed to extend in a direction of approximately 45 degrees with respect to the x-axis direction. That is, the wire grid polarizer 10-4-2 is obtained by tilting the wire grid polarizer 10-3-2 illustrated in FIG. 3 at approximately 45 degrees counterclockwise. In addition, the extension direction of the wire grid polarizer 10-4-1 and the extension direction of the polarizer 10-4-2 having a wire grid are orthogonal to each other.

As illustrated in FIG. 4B, in the pixel P4-1, an on-chip lens 4, a color filter 3 (in FIG. 4B, for example, a color filter that transmits green light (green filter) 3G), a wire grid upper film 31, and a photoelectric conversion element 2 are formed in order from a light incident side (the upper side in FIG. 4B). The wire grid polarizer 10-4-1 is formed on a back surface 2R of the photoelectric conversion element 2, which is a light incident side. That is, at least a portion of the photoelectric conversion element 2 on the back surface 2R side of the photoelectric conversion element 2 is a medium, and the medium is disposed around the wire grid polarizer 10-4-1.

As illustrated in FIG. 4B, in the pixel P4-2, the on-chip lens 4, the color filter 3 (in FIG. 4B, for example, a color filter that transmits red light (red filter) 3R), the wire grid upper film 31, and the photoelectric conversion element 2 are formed in order from a light incident side (the upper side in FIG. 4B). The wire grid polarizer 10-4-2 is formed on the back surface 2R of the photoelectric conversion element 2, which is a light incident side. That is, at least a portion of the photoelectric conversion element 2 on the back surface 2R side of the photoelectric conversion element 2 is a medium, and the medium is disposed around the wire grid polarizer 10-4-2.

In the solid-state imaging device 104, when an optimum refractive index n for improving an extinction ratio is substantially the same as the refractive index n of the photoelectric conversion element 2, the wire grid polarizers 10-4-1 and 10-4-2 are formed on a back surface 2R of the photoelectric conversion element 2. It is preferable that a refractive index n of a material forming the wire grid upper film 31 included in the solid-state imaging device 104 be close to or substantially equal to the refractive index n of the photoelectric conversion element 2. The solid-state imaging device 104 has a structure in which an effective wavelength of incident light is modulated by the refractive index of the photoelectric conversion layer, so that the extinction ratio can be improved. The effective wavelength of the incident light can be modulated by the refractive index of the photoelectric conversion layer. Note that the wire grid polarizers 10-4-1 and 10-4-2 are formed not only on the back surface 2R of the photoelectric conversion element 2, but also on the front surface (a side opposite to a light incident side) of the photoelectric conversion element 2.

In the solid-state imaging device 104, two wire grid polarizers 10-3-1 to 10-3-2 included in the solid-state imaging device 103 may be respectively disposed in at least two pixels (not illustrated) other than the pixels P4-1 to P4-2. Thereby, in the solid-state imaging device 104, four types of wire grid polarizers having wires extending in directions of approximately 0 degrees, approximately 45 degrees, approximately 90 degrees, and approximately 135 degrees with respect to the x-axis direction can generate light having four types of polarization states.

The above-described contents of the solid-state imaging device of the fourth embodiment (Example 4 of a solid-state imaging device) according to the present technology can be applied to the above-described solid-state imaging devices of the first to third embodiments according to the present technology and solid-state imaging devices of fifth to eighth embodiments according to the present technology to be described later, unless there is no particular technical contradiction.

### 6. Fifth Embodiment (Example 5 of Solid-State Imaging Device)

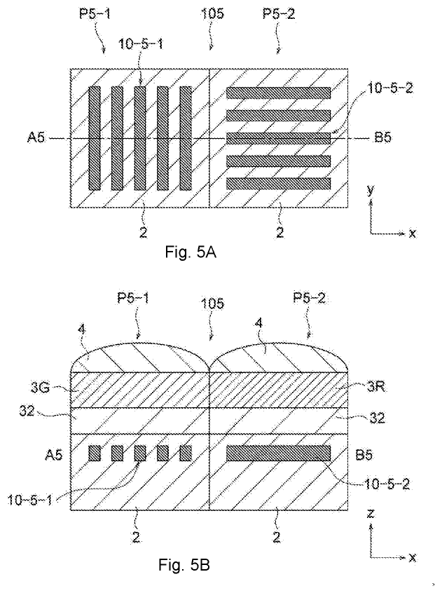

The solid-state imaging device of the fifth embodiment (Example 5 of the solid-state imaging device) according to the present technology will be described with reference to FIG. 5.

FIG. 5 is a diagram illustrating a solid-state imaging device 105 which is the solid-state imaging device of the fifth embodiment according to the present technology. Specifically, FIG. 5A is a plan view of two pixels (pixels P5-1 and P5-2) of the solid-state imaging device 105 (a planar layout diagram of two pixels of the solid-state imaging device 105 from a light incident side), and FIG. 5B is a cross-sectional view of two pixels (pixels P5-1 and P5-2) of the solid-state imaging device 105 along line A5-B5 illustrated in FIG. 5A.

As illustrated in FIG. 5A, in the pixel P5-1, a polarizer 10-5-1 having a wire grid made of a conductive light shielding material (hereinafter referred to as a wire grid polarizer 10-5-1) is formed to extend in a direction of approximately 90 degrees (y-axis direction) with respect to the x-axis direction. On the other hand, in the pixel P5-2, a polarizer 10-5-2 having a wire grid made of a conductive light shielding material (hereinafter referred to as a wire grid polarizer 10-5-2) is formed to extend in a direction of approximately 0 degrees (x-axis direction) with respect to the x-axis direction. In addition, the extension direction of the wire grid polarizer 10-5-1 and the extension direction of the polarizer 10-5-2 having a wire grid are orthogonal to each other.

As illustrated in FIG. 5B, in the pixel P5-1, an on-chip lens 4, a color filter 3 (in FIG. 5B, for example, a color filter that transmits green light (green filter) 3G), a wire grid upper film 32, and a photoelectric conversion element 2 are formed in order from a light incident side (the upper side in FIG. 5B). The wire grid polarizer 10-5-1 is formed to be embedded in the photoelectric conversion element 2. That is, at least a portion of the photoelectric conversion element 2 is a medium, and the medium is disposed around the wire grid polarizer 10-5-1.

As illustrated in FIG. 5B, in the pixel P5-2, the on-chip lens 4, the color filter 3 (in FIG. 5B, for example, a color filter that transmits red light (red filter) 3R), the wire grid upper film 32, and the photoelectric conversion element 2 are formed in order from a light incident side (the upper side in FIG. 5B). The wire grid polarizer 10-5-2 is formed to be embedded in the photoelectric conversion element 2. That is, at least a portion of the photoelectric conversion element 2 is a medium, and the medium is disposed around the wire grid polarizer 10-5-2.

In the solid-state imaging device 105, when an optimum refractive index n for improving an extinction ratio is substantially the same as the refractive index n of the photoelectric conversion element 2, the wire grid polarizers 10-5-1 and 10-5-2 are formed to be embedded in the photoelectric conversion element 2. It is preferable that a refractive index n of a material forming the wire grid upper film 32 included in the solid-state imaging device 105 be close to or substantially equal to the refractive index n of the photoelectric conversion element 2. The solid-state imaging device 105 has a structure in which an effective wavelength of incident light is modulated by the refractive index of the photoelectric conversion layer, so that the extinction ratio can be improved. The effective wavelength of the incident light can be modulated by the refractive index of the photoelectric conversion layer.

The above-described contents of the solid-state imaging device of the fifth embodiment (Example 5 of a solid-state imaging device) according to the present technology can be applied to the above-described solid-state imaging devices of the first to fourth embodiments according to the present technology and solid-state imaging devices of sixth and eighth embodiments according to the present technology to be described later, unless there is no particular technical contradiction.

### 7. Sixth Embodiment (Example 6 of Solid-State Imaging Device)

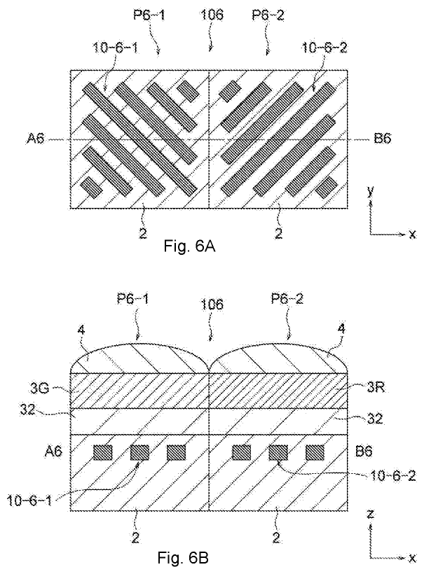

The solid-state imaging device of the sixth embodiment (Example 6 of a solid-state imaging device) according to the present technology will be described using FIG. 6.

FIG. 6 is a diagram illustrating a solid-state imaging device 106 which is the solid-state imaging device of the sixth embodiment according to the present technology. Specifically, FIG. 6A is a plan view of two pixels (pixels P6-1 and P6-2) of the solid-state imaging device 106 (a planar layout diagram of two pixels of the solid-state imaging device 106 from a light incident side), and FIG. 6B is a cross-sectional view of two pixels (pixels P6-1 and P6-2) of the solid-state imaging device 106 along line A6-B6 illustrated in FIG. 6A.

As illustrated in FIG. 6A, in the pixel P6-1, a polarizer 10-6-1 having a wire grid made of a conductive light shielding material (hereinafter referred to as a wire grid polarizer 10-6-1) is formed to extend in a direction of approximately 135 degrees with respect to the x-axis direction. That is, the wire grid polarizer 10-6-1 is obtained by tilting the wire grid polarizer 10-5-1 illustrated in FIG. 5 at approximately 45 degrees counterclockwise. On the other hand, in the pixel P6-2, the polarizer 10-6-2 having a wire grid made of a conductive light shielding material (hereinafter referred to as a wire grid polarizer 10-6-2) is formed to extend in a direction of approximately 45 degrees with respect to the x-axis direction. That is, the wire grid polarizer 10-6-2 is obtained by tilting the wire grid polarizer 10-5-2 illustrated in FIG. 5 at approximately 45 degrees counterclockwise. In addition, the extension direction of the wire grid polarizer 10-6-1 and the extension direction of the polarizer 10-6-2 having a wire grid are orthogonal to each other.

As illustrated in FIG. 6B, in the pixel P6-1, an on-chip lens 4, a color filter 3 (in FIG. 6B, for example, a color filter that transmits green light (green filter) 3G), a wire grid upper film 32, and a photoelectric conversion element 2 are formed in order from a light incident side (the upper side in FIG. 6B). The wire grid polarizer 10-6-1 is formed to be embedded in the photoelectric conversion element 2. That is, at least a portion of the photoelectric conversion element 2 is a medium, and the medium is disposed around the wire grid polarizer 10-6-1.

As illustrated in FIG. 6B, in the pixel P6-2, the on-chip lens 4, the color filter 3 (in FIG. 6B, for example, a color filter that transmits red light (red filter) 3R), the wire grid upper film 32, and the photoelectric conversion element 2 are formed in order from a light incident side (the upper side in FIG. 6B). The wire grid polarizer 10-6-2 is formed to be embedded in the photoelectric conversion element 2. That is, at least a portion of the photoelectric conversion element 2 is a medium, and the medium is disposed around the wire grid polarizer 10-6-2.

In the solid-state imaging device 106, when an optimum refractive index n for improving an extinction ratio is substantially the same as the refractive index n of the photoelectric conversion element 2, the wire grid polarizers 10-6-1 and 10-6-2 are formed to be embedded in the photoelectric conversion element 2. It is preferable that a refractive index n of a material forming the wire grid upper film 32 included in the solid-state imaging device 106 be close to or substantially equal to the refractive index n of the photoelectric conversion element 2. The solid-state imaging device 106 has a structure in which an effective wavelength of incident light is modulated by the refractive index of the photoelectric conversion layer, so that the extinction ratio can be improved. The effective wavelength of the incident light can be modulated by the refractive index of the photoelectric conversion layer.

In the solid-state imaging device 106, two wire grid polarizers 10-5-1 to 10-5-2 included in the solid-state imaging device 105 may be respectively disposed in at least two pixels (not illustrated) other than the pixels P6-1 to P6-2. Thereby, in the solid-state imaging device 106, four types of wire grid polarizers having wires extending in directions of approximately 0 degrees, approximately 45 degrees, approximately 90 degrees, and approximately 135 degrees with respect to the x-axis direction can generate light having four types of polarization states.

The above-described contents of the solid-state imaging device of the sixth embodiment (Example 6 of a solid-state imaging device) according to the present technology can be applied to the above-described solid-state imaging devices of the first to fifth embodiments according to the present technology and solid-state imaging devices of seventh and eighth embodiments according to the present technology to be described later, unless there is no particular technical contradiction.

### 8. Seventh Embodiment (Example 7 of Solid-State Imaging Device)

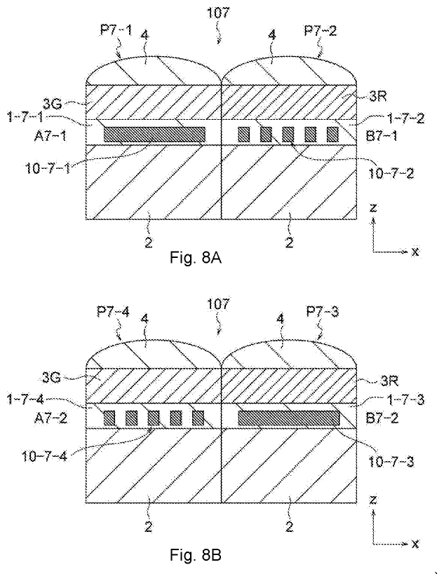

The solid-state imaging device of the seventh embodiment (Example 7 of a solid-state imaging device) according to the present technology will be described with reference to FIGS. 7 and 8.

FIG. 7 is a plan view of a solid-state imaging device 107 which is the solid-state imaging device of the seventh embodiment according to the present technology, and specifically, is a plan view of four pixels (pixels P7-1, P7-2, P7-3, and P7-4) of the solid-state imaging device 107 (a planar layout diagram of four pixels of the solid-state imaging device 107 from a light incident side).

FIG. 8 is a cross-sectional view of the solid-state imaging device 107 which is the solid-state imaging device of the seventh embodiment according to the present technology. Specifically, FIG. 8A is a cross-sectional view of two pixels (pixels P7-1 and P7-2) of the solid-state imaging device 107 along line A7-1-B7-1 illustrated in FIG. 7, and FIG. 8B is a cross-sectional view of two pixels (pixels P7-3 and P7-4) of the solid-state imaging device 107 along line A7-2-B7-2 illustrated in FIG. 7.

First, description will be made with reference to FIG. 7.

As illustrated in FIG. 7, in the pixel P7-1, a polarizer 10-7-1 having a wire grid made of a conductive light shielding material (hereinafter referred to as a wire grid polarizer 10-7-1) is formed to extend in a direction of approximately 0 degrees (x-axis direction) with respect to the x-axis direction. In the pixel P7-2, a polarizer 10-7-2 having a wire grid made of a conductive light shielding material (hereinafter referred to as a wire grid polarizer 10-7-2) is formed to extend in a direction of approximately 90 degrees (y-axis direction) with respect to the x-axis direction. In the pixel P7-3, a polarizer 10-7-3 having a wire grid made of a conductive light shielding material (hereinafter referred to as a wire grid polarizer 10-7-3) is formed to extend in a direction of approximately 0 degrees (x-axis direction) with respect to the x-axis direction. In the pixel P7-2, a polarizer 10-7-4 having a wire grid made of a conductive light shielding material (hereinafter referred to as a wire grid polarizer 10-7-4) is formed to extend in a direction of approximately 90 degrees (y-axis direction) with respect to the x-axis direction.

In addition, the extension direction of the wire grid polarizer 10-7-1 and the extension direction of the polarizer 10-7-2 having a wire grid are orthogonal to each other, and the extension direction of the wire grid polarizer 10-7-3 and the extension direction of the polarizer 10-7-4 having a wire grid are orthogonal to each other.

Next, description will be made with reference to FIG. 8.

As illustrated in FIG. 8A, in the pixel P7-1, an on-chip lens 4, a color filter 3 (in FIG. 8A, for example, a color filter that transmits green light (green filter) 3G), a medium 1-7-1, and a photoelectric conversion element 2 are formed in order from a light incident side (the upper side in FIG. 8A). The wire grid polarizer 10-7-1 is formed in the medium 1-7-1. That is, the medium 1-7-1 is disposed around the wire grid polarizer 10-7-1.

In the pixel P7-2, the on-chip lens 4, the color filter 3 (in FIG. 8A, for example, a color filter (red filter) 3R that transmits red light), the medium 1-7-2, and photoelectric conversion element 2 are formed in order from a light incident side (the upper side in FIG. 8A). The wire grid polarizer 10-7-2 is formed in the medium 1-7-2. That is, the medium 1-7-2 is disposed around the wire grid polarizer 10-7-2.

As illustrated in FIG. 8B, in the pixel P7-4, the on-chip lens 4, the color filter 3 (in FIG. 8B, for example, a color filter that transmits green light (green filter) 3G), a medium 1-7-4, and the photoelectric conversion element 2 are formed in order from a light incident side (the upper side in FIG. 8B). The wire grid polarizer 10-7-4 is formed in the medium 1-7-4. That is, the medium 1-7-4 is disposed around the wire grid polarizer 10-7-4.

In the pixel P7-3, the on-chip lens 4, the color filter 3 (in FIG. 8B, for example, a color filter (red filter) 3R that transmits red light), a medium 1-7-3, and the photoelectric conversion element 2 are formed in order from a light incident side (the upper side in FIG. 8B). The wire grid polarizer 10-7-3 is formed in the medium 1-7-3. That is, the medium 1-7-3 is disposed around the wire grid polarizer 10-7-3.

The solid-state imaging device 107 has a structure in which the media 1-7-1 and 1-7-2 having an optimum refractive index n for improving an extinction ratio are selectively disposed with respect to a first target wavelength (referred to as λa), and the media 1-7-3 and 1-7-4 having an optimum refractive index n for improving an extinction ratio are selectively disposed with respect to a second target wavelength (referred to as λb). Note that the first target wavelength (λa) and the second target wavelength (λb) are different wavelengths.

Note that, although not illustrated in the drawing, the solid-state imaging device 107 may have a structure in which the medium 1-7-1 having an optimum refractive index n for improving an extinction ratio is selectively disposed with respect to a first target wavelength (referred to as λa), the medium 1-7-2 having an optimum refractive index n for improving an extinction ratio is selectively disposed with respect to a third target wavelength (referred to as λc), the medium 1-7-3 having an optimum refractive index n for improving an extinction ratio is selectively disposed with respect to a second target wavelength (referred to as λb), and the medium 1-7-4 having an optimum refractive index n for improving an extinction ratio is selectively disposed with respect to a fourth target wavelength (referred to as λd). Note that the first target wavelength (λa), the second target wavelength (λb), the third target wavelength (λc), and the fourth target wavelength (λd) are different wavelengths.

According to the solid-state imaging device 107, with respect to each target wavelength of a plurality of different target wavelengths, an extinction ratio can be improved by selectively disposing a medium having an optimum refractive index n for improving an extinction ratio for each pixel (may be, for example, for every multiple pixels such as every two pixels).

The above-described contents of the solid-state imaging device of the seventh embodiment (Example 7 of a solid-state imaging device) according to the present technology can be applied to the above-described solid-state imaging devices of the first to sixth embodiments according to the present technology and a solid-state imaging device of an eighth embodiment according to the present technology to be described later, unless there is no particular technical contradiction.

### 9. Eighth Embodiment (Example 8 of Solid-State Imaging Device)

The solid-state imaging device of the eighth embodiment (Example 8 of a solid-state imaging device) according to the present technology will be described using FIGS. 9 and 10.

FIG. 9 is a plan view of a solid-state imaging device 108 which is the solid-state imaging device of the eighth embodiment according to the present technology, and specifically, is a plan view of four pixels (pixels P8-1, P8-2, P8-3, and P8-4) of the solid-state imaging device 108 (a planar layout diagram of four pixels of the solid-state imaging device 108 from a light incident side).

FIG. 10 is a cross-sectional view of the solid-state imaging device 108 which is the solid-state imaging device of the eighth embodiment according to the present technology. Specifically, FIG. 10A is a cross-sectional view of two pixels (pixels P8-1 and P8-2) of the solid-state imaging device 108 along line A8-1-B8-1 illustrated in FIG. 9, and FIG. 10B is a cross-sectional view of two pixels (pixels P8-3 and P8-4) of the solid-state imaging device 108 along line A8-2-B8-2 illustrated in FIG. 9.

First, description will be made with reference to FIG. 9.

As illustrated in FIG. 9, in the pixel P8-1, a polarizer 10-8-1 having a wire grid made of a conductive light shielding material (hereinafter referred to as a wire grid polarizer 10-8-1) is formed to extend in a direction of approximately 45 degrees with respect to the x-axis direction. That is, the wire grid polarizer 10-8-1 is obtained by tilting the wire grid polarizer 10-7-1 illustrated in FIG. 7 at approximately 45 degrees counterclockwise. In the pixel P8-2, the polarizer 10-8-2 having a wire grid made of a conductive light shielding material (hereinafter referred to as a wire grid polarizer 10-8-2) is formed to extend in a direction of approximately 135 degrees with respect to the x-axis direction. That is, the wire grid polarizer 10-8-2 is obtained by tilting the wire grid polarizer 10-7-2 illustrated in FIG. 7 at approximately 45 degrees counterclockwise. In the pixel P8-3, a polarizer 10-8-3 having a wire grid made of a conductive light shielding material (hereinafter referred to as a wire grid polarizer 10-8-3) is formed to extend in a direction of approximately 45 degrees with respect to the x-axis direction. That is, the wire grid polarizer 10-8-3 is obtained by tilting the wire grid polarizer 10-7-3 illustrated in FIG. 7 counterclockwise at approximately 45 degrees. In the pixel P8-4, a polarizer 10-8-4 having a wire grid made of a conductive light shielding material (hereinafter referred to as a wire grid polarizer 10-8-4) is formed to extend in a direction of approximately 135 degrees with respect to the x-axis direction. That is, the wire grid polarizer 10-8-4 is obtained by tilting the wire grid polarizer 10-7-4 illustrated in FIG. 7 counterclockwise at approximately 45 degrees.

In addition, the extension direction of the wire grid polarizer 10-8-1 and the extension direction of the polarizer 10-8-2 having a wire grid are orthogonal to each other, and the extension direction of the wire grid polarizer 10-8-3 and the extension direction of the polarizer 10-8-4 having a wire grid are orthogonal to each other.

Next, description will be made with reference to FIG. 10.

As illustrated in FIG. 10A, in the pixel P8-1, an on-chip lens 4, a color filter 3 (in FIG. 10A, for example, a color filter that transmits green light (green filter) 3G), a medium 1-8-1, and a photoelectric conversion element 2 are formed in order from a light incident side (the upper side in FIG. 10A). The wire grid polarizer 10-8-1 is formed in the medium 1-8-1. That is, the medium 1-8-1 is disposed around the wire grid polarizer 10-8-1.

In the pixel P8-2, the on-chip lens 4, the color filter 3 (in FIG. 10A, for example, a color filter (red filter) 3R that transmits red light), the medium 1-8-2, and photoelectric conversion element 2 are formed in order from a light incident side (the upper side in FIG. 10A). The wire grid polarizer 10-8-2 is formed in the medium 1-8-2. That is, the medium 1-8-2 is disposed around the wire grid polarizer 10-8-2.

As illustrated in FIG. 10B, in the pixel P8-4, the on-chip lens 4, the color filter 3 (in FIG. 10B, for example, a color filter that transmits green light (green filter) 3G), a medium 1-8-4, and the photoelectric conversion element 2 are formed in order from a light incident side (the upper side in FIG. 10B). The wire grid polarizer 10-8-4 is formed in the medium 1-8-4. That is, the medium 1-8-4 is disposed around the wire grid polarizer 10-8-4.

In the pixel P8-3, the on-chip lens 4, the color filter 3 (in FIG. 10B, for example, a color filter (red filter) 3R that transmits red light), a medium 1-8-3, and the photoelectric conversion element 2 are formed in order from a light incident side (the upper side in FIG. 10B). The wire grid polarizer 10-8-3 is formed in the medium 1-8-3. That is, the medium 1-8-3 is disposed around the wire grid polarizer 10-8-3.

The solid-state imaging device 108 has a structure in which the media 1-8-1 and 1-8-2 having an optimum refractive index n for improving an extinction ratio are selectively disposed with respect to a first target wavelength (referred to as λa), and the media 1-8-3 and 1-8-4 having an optimum refractive index n for improving an extinction ratio are selectively disposed with respect to a second target wavelength (referred to as λb). Note that the first target wavelength (λa) and the second target wavelength (λb) are different wavelengths.

Note that, although not illustrated in the drawing, the solid-state imaging device 108 may have a structure in which the medium 1-8-1 having an optimum refractive index n for improving an extinction ratio is selectively disposed with respect to a first target wavelength (referred to as λa), the medium 1-8-2 having an optimum refractive index n for improving an extinction ratio is selectively disposed with respect to a third target wavelength (referred to as λc), the medium 1-8-3 having an optimum refractive index n for improving an extinction ratio is selectively disposed with respect to a second target wavelength (referred to as λb), and the medium 1-8-4 having an optimum refractive index n for improving an extinction ratio is selectively disposed with respect to a fourth target wavelength (referred to as λd). Note that the first target wavelength (λa), the second target wavelength (λb), the third target wavelength (λc), and the fourth target wavelength (λd) are different wavelengths.

According to the solid-state imaging device 108, with respect to each target wavelength of a plurality of different target wavelengths, an extinction ratio can be improved by selectively disposing a medium having an optimum refractive index n for improving an extinction ratio for each pixel (may be, for example, for every multiple pixels such as every two pixels).

In the solid-state imaging device 108, four wire grid polarizers 10-7-1 to 10-7-4 included in the solid-state imaging device 107 may be respectively disposed in at least four pixels (not illustrated) other than the pixels P8-1 to P8-4. Thereby, in the solid-state imaging device 108, four types of wire grid polarizers having wires extending in directions of approximately 0 degrees, approximately 45 degrees, approximately 90 degrees, and approximately 135 degrees with respect to the x-axis direction can generate light having four types of polarization states.

The above-described contents of the solid-state imaging device of the eighth embodiment (Example 8 of a solid-state imaging device) according to the present technology can be applied to the above-described solid-state imaging devices of the first to seventh embodiments according to the present technology, unless there is no particular technical contradiction.

### 10. Ninth Embodiment (Example of Electronic Equipment)

Electronic equipment of a ninth embodiment according to the present technology is electronic equipment on which the solid-state imaging device of any one embodiment among the solid-state imaging devices of the first to eighth embodiments according to the present technology is mounted.

### 11. Example of Use of Solid-State Imaging Device to which the Present Technology is Applied

FIG. 19 is a diagram illustrating examples of use of the solid-state imaging devices of the first to eighth embodiments according to the present technology as an image sensor.

The solid-state imaging devices of the first to eighth embodiments described above can be used in various cases for sensing light such as visible light, infrared light, ultraviolet light, and X-rays as described below. That is, as illustrated in FIG. 19, the solid-state imaging device of any one embodiment among the solid-state imaging devices of the first to eighth embodiments according to the present technology can be used in devices (for example, the electronic equipment of the above-described ninth embodiment) which are used in, for example, the field of appreciation for capturing images to be used for appreciation, the field of transportation, the field of home appliances, the field of medical treatment/healthcare, the field of security, the field of beauty, the field of sports, the field of agriculture, and the like.

Specifically, in the field of appreciation, the solid-state imaging device of any one embodiment among the solid-state imaging devices of the first to eighth embodiments according to the present technology can be used in devices for capturing images provided for appreciation, such as a digital camera, a smartphone, and a mobile phone with a camera function.

In the field of traffic, the solid-state imaging device of any one embodiment among the solid-state imaging devices of the first to eighth embodiments according to the present technology can be used in devices provided for traffic, such as an in-vehicle sensor that images the front, rear, surroundings, inside, and the like of a vehicle, a monitoring camera that monitors traveling vehicles and roads, and a distance measuring sensor that measures a distance between vehicles, and the like for safe driving such as automatic stop, recognition of a driver's conditions, and the like.

In the field of home appliances, the solid-state imaging device of any one embodiment among the solid-state imaging devices of the first to eighth embodiments according to the present technology can be used in devices provided for home appliances, such as a television receiver, a refrigerator, and an air conditioner, for example, in order to image a user's gesture and operate equipment in response to the gesture.

In the field of medical treatment and health care, the solid-state imaging device of any one embodiment among the solid-state imaging devices of the first to eighth embodiments according to the present technology can be used in devices provided for medical treatment and health care, such as an endoscope and a device that performs angiography by receiving infrared light.

In the field of security, the solid-state imaging device of any one embodiment among the solid-state imaging devices of the first to eighth embodiments according to the present technology can be used in devices provided for security, such as a surveillance camera for crime prevention and a camera for person authentication.

In the field of beauty, the solid-state imaging device of any one embodiment among the solid-state imaging devices of the first to eighth embodiments according to the present technology can be used in devices provided for beauty such as a skin measuring instrument that images the skin and a microscope that images the scalp.

In the field of sports, the solid-state imaging device of any one embodiment among the solid-state imaging devices of the first to eighth embodiments according to the present technology can be used in devices provided for sports, such as an action camera and a wearable camera for sports applications.

In the field of agriculture, the solid-state imaging device of any one embodiment among the solid-state imaging devices of the first to eighth embodiments according to the present technology can be used in devices provided for agriculture such as a camera that monitors the conditions of fields and crops.

Next, examples of use of the solid-state imaging devices of the first to eighth embodiments according to the present technology will be specifically described. For example, the solid-state imaging device of any one embodiment among the solid-state imaging devices of the first to eighth embodiments according to the present technology described above is used. Specifically, a solid-state imaging device 101Z can be applied to any type of electronic equipment having an imaging function, such as a camera system such as a digital still camera or a video camera, or a mobile phone having an imaging function. FIG. 20 illustrates a schematic configuration of electronic equipment 102Z (camera) as an example. The electronic equipment 102Z is, for example, a video camera capable of capturing still images or moving images, and includes the solid-state imaging device 101Z, an optical system (optical lens) 310, a shutter device 311, a drive unit 313 that drives the solid-state imaging device 101Z and the shutter device 311, and a signal processing unit 312.

The optical system 310 guides image light (incident light) from a subject to a pixel portion of the solid-state imaging device 101Z. This optical system 310 may be constituted by a plurality of optical lenses. The shutter device 311 controls a light irradiation period and a light shielding period for the solid-state imaging device 101Z. The drive unit 313 controls a transfer operation of the solid-state imaging device 101Z and a shutter operation of the shutter device 311.

The signal processing unit 312 performs various types of signal processing on signals output from the solid-state imaging device 101Z. A video signal Dout after signal processing is stored in a storage medium such as a memory or is output to a monitor or the like.

### 12. Example of Application to Endoscopic Surgery System

The present technology can be applied to various products. For example, the technology according to the present disclosure (the present technology) may be applied to an endoscopic surgery system.

FIG. 21 is a diagram illustrating an example of a schematic configuration of an endoscopic surgery system to which the technology according to the present disclosure (the present technology) may be applied.

FIG. 21 illustrates a state in which a surgeon (doctor) 11131 is operating on a patient 11132 on a patient bed 11133 using an endoscopic surgery system 11000. As illustrated in the drawing, the endoscopic surgery system 11000 is constituted by an endoscope 11100, another surgical instrument 11110 such as a pneumoperitoneum tube 11111 or an energized treatment tool 11112, a support arm device 11120 that supports the endoscope 11100, and a cart 11200 mounted with various devices for endoscopic surgery.

The endoscope 11100 includes a lens barrel 11101 of which a region having a predetermined length from a tip thereof is inserted into a body cavity of the patient 11132, and a camera head 11102 connected to a base end of the lens barrel 11101. In the example illustrated in the drawing, the endoscope 11100 configured as a so-called rigid endoscope having the rigid lens barrel 11101 is illustrated, but the endoscope 11100 may be configured as a so-called flexible endoscope having a flexible lens barrel.

The tip of the lens barrel 11101 is provided with an opening into which an objective lens is fitted. A light source device 11203 is connected to the endoscope 11100, light generated by the light source device 11203 is guided to the tip of the lens barrel 11101 by a light guide extended to the inside of the lens barrel 11101, and the light is radiated toward an observation target in the body cavity of the patient 11132 through the objective lens. The endoscope 11100 may be a direct-viewing endoscope, an oblique-viewing endoscope, or a side-viewing endoscope.

An optical system and an imaging element are provided inside the camera head 11102 and light (observation light) reflected from the observation target is focused on the imaging element by the optical system. The observation light is photoelectrically converted by the imaging element, and an electrical signal corresponding to the observation light, that is, an image signal corresponding to an observation image is generated. The image signal is transmitted as RAW data to a camera control unit (CCU) 11201.

The CCU 11201 is constituted by a central processing unit (CPU) and a graphics processing unit (GPU) or the like and controls the overall operations of the endoscope 11100 and the display device 11202. Further, the CCU 11201 performs, on the image signal received from the camera head 11102, various kinds of image processing for displaying an image based on the image signal, for example, development processing (demosaic processing).

The display device 11202 displays the image based on the image signal subjected to the image processing by the CCU 11201 under the control of the CCU 11201.

The light source device 11203 is constituted by, for example, a light source such as a light emitting diode (LED) and supplies the endoscope 11100 with irradiation light when photographing a surgical site or the like.

An input device 11204 is an input interface for endoscopic surgery system 11000. A user can input various information and instructions to the endoscopic surgery system 11000 via the input device 11204. For example, the user inputs an instruction or the like to change the imaging conditions (the type of irradiation light, magnification, focal length, and the like) by the endoscope 11100.

A treatment tool control device 11205 controls driving of the energized treatment tool 11112 for cauterization or incision of a tissue, sealing of blood vessel, or the like. A pneumoperitoneum device 11206 sends gas into the body cavity of the patient 11132 via the pneumoperitoneum tube 11111 in order to inflate the body cavity for the purpose of securing a field of view using the endoscope 11100 and a working space of the surgeon. A recorder 11207 is a device capable of recording various types of information on surgery. A printer 11208 is a device capable of printing various types of information on surgery in various formats such as text, images, and graphs.

Note that, the light source device 11203 that supplies irradiation light for imaging a surgical site to the endoscope 11100 can be constituted by an LED, a laser light source, or a white light source constituted by a combination thereof. In a case where the white light source is constituted by a combination of RGB laser light sources, the intensity and timing of output of each color (each wavelength) can be controlled with high accuracy, and thus it is possible to adjust the white balance of a captured image in the light source device 11203. Further, in this case, by time-divisionally irradiating an observation target with laser light from the RGB laser light sources and controlling driving of the imaging element of the camera head 11102 in synchronization with the irradiation timing, it is also possible to time-divisionally capture images corresponding to RGB. According to this method, it is possible to obtain a color image without providing a color filter in the imaging element.

Further, driving of the light source device 11203 may be controlled so that the intensity of output light is changed at predetermined time intervals. The driving of the imaging element of the camera head 11102 is controlled in synchronization with a timing of changing the intensity of the light, and images are acquired in a time division manner and combined, such that an image having a high dynamic range without so-called blackout and whiteout can be generated.

In addition, the light source device 11203 may be configured to be able to supply light in a predetermined wavelength band corresponding to a special light observation. In the special light observation, so-called narrow band imaging is performed, in which a predetermined tissue such as a blood vessel in a superficial portion of mucous membrane is imaged with a high contrast through irradiation of light with a narrower band than irradiation light (that is, white light) during a normal observation by using, for example, the wavelength dependence of light absorption in a body tissue. Alternatively, in the special light observation, a fluorescence observation may be made, in which an image is captured by fluorescence generated by irradiation of excitation light. In the fluorescence observation, fluorescence from a body tissue can be observed by irradiating the body tissue with excitation light (self-fluorescence observation) or a fluorescent image can be captured by locally injecting a reagent, for example, indocyanine green (ICG) into a body tissue and irradiating the body tissue with excitation light corresponding to the fluorescence wavelength of the reagent. The light source device 11203 can be configured to be able to supply narrow band light and/or excitation light corresponding to such special light observation.

FIG. 22 is a block diagram illustrating an example of a functional configuration of the camera head 11102 and the CCU 11201 illustrated in FIG. 21.

The camera head 11102 includes a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other by a transmission cable 11400.

The lens unit 11401 is an optical system provided in a portion for connection to the lens barrel 11101. Observation light taken from a tip of the lens barrel 11101 is guided to the camera head 11102 and is incident on the lens unit 11401. The lens unit 11401 is configured in combination of a plurality of lenses including a zoom lens and a focus lens.

The imaging unit 11402 is constituted by an imaging element. The imaging element constituting the imaging unit 11402 may be one (so-called single-plate type) or plural (so-called multi-plate type). When the imaging unit 11402 is configured as a multi-plate type, for example, image signals corresponding to RGB may be generated by each imaging element, and a color image may be obtained by synthesizing the image signals. Alternatively, the imaging unit 11402 may be configured to have a pair of imaging elements for respectively acquiring right-eye and left-eye image signals corresponding to three-dimensional (3D) display. The performed 3D display allows the surgeon 11131 to more accurately ascertain the depth of a living tissue in the surgical site. Note that, in a case where the imaging unit 11402 is configured as a multi-plate type, a plurality of systems of lens units 11401 may be provided in correspondence to the imaging elements.

In addition, the imaging unit 11402 need not necessarily be provided in the camera head 11102. For example, the imaging unit 11402 may be provided immediately after the objective lens inside the lens barrel 11101.

The drive unit 11403 is constituted by an actuator and the zoom lens and the focus lens of the lens unit 11401 are moved by a predetermined distance along an optical axis under the control of the camera head control unit 11405. Thereby, the magnification and focus of the image captured by the imaging unit 11402 can be adjusted appropriately.

The communication unit 11404 is constituted by a communication device for transmitting and receiving various types of information to and from the CCU 11201. The communication unit 11404 transmits the image signal obtained from the imaging unit 11402 as RAW data to the CCU 11201 via the transmission cable 11400.

In addition, the communication unit 11404 receives a control signal for controlling driving of the camera head 11102 from the CCU 11201 and supplies the control signal to the camera head control unit 11405. The control signal includes, for example, information regarding imaging conditions such as information indicating designation of a frame rate of a captured image, information indicating designation of an exposure value at the time of imaging, and/or information indicating designation of a magnification and a focus of the captured image.

Note that imaging conditions such as the foregoing frame rate, exposure value, magnification, and focus may be designated appropriately by the user or may be set automatically by the control unit 11413 of the CCU 11201 based on the acquired image signal. In the latter case, a so-called auto exposure (AE) function, an auto focus (AF) function, and an auto white balance (AWB) function are provided in the endoscope 11100.

The camera head control unit 11405 controls driving of the camera head 11102 based on the control signal received from the CCU 11201 via the communication unit 11404.

The communication unit 11411 is constituted of a communication device that transmits and receives various kinds of information to and from the camera head 11102. The communication unit 11411 receives an image signal transmitted via the transmission cable 11400 from the camera head 11102.

Further, the communication unit 11411 transmits the control signal for controlling the driving of the camera head 11102 to the camera head 11102. The image signal or the control signal can be transmitted through electric communication, optical communication, or the like.

The image processing unit 11412 performs various types of image processing on the image signal that is the RAW data transmitted from the camera head 11102.

The control unit 11413 performs various kinds of control on imaging of a surgical site by the endoscope 11100, display of a captured image obtained through imaging of a surgical site, or the like. For example, the control unit 11413 generates a control signal for controlling driving of the camera head 11102.

In addition, the control unit 11413 causes the display device 11202 to display a captured image showing a surgical site or the like based on an image signal subjected to the image processing by the image processing unit 11412. At this time, the control unit 11413 may recognize various objects in the captured image using various image recognition technology. For example, the control unit 11413 can recognize a surgical instrument such as forceps, a specific biological site, bleeding, mist or the like at the time of using the energized treatment tool 11112, or the like by detecting the shape, color, or the like of an edge of an object included in the captured image. When the display device 11202 is caused to display a captured image, the control unit 11413 may superimpose various kinds of surgery support information on an image of the surgical site for display using a recognition result of the captured image. By displaying the surgery support information in a superimposed manner and presenting it to the surgeon 11131, a burden on the surgeon 11131 can be reduced, and the surgeon 11131 can reliably proceed with the surgery.

The transmission cable 11400 that connects the camera head 11102 and the CCU 11201 is an electrical signal cable compatible with communication of electrical signals, an optical fiber compatible with optical communication, or a composite cable of these.

Here, although wired communication is performed using the transmission cable 11400 in the illustrated example, communication between the camera head 11102 and the CCU 11201 may be performed wirelessly.

An example of an endoscopic surgery system to which the technology according to the present disclosure can be applied has been described above. The technology according to the present disclosure can be applied to the endoscope 11100, the camera head 11102 (the imaging unit 11402 thereof), and the like among the configurations described above. Specifically, the solid-state imaging device according to the present technology can be applied to the imaging unit 10402. The technology according to the present disclosure is applied to the endoscope 11100, the camera head 11102 (the imaging unit 11402 thereof), and the like, and thus it is possible to improve the performance of the endoscope 11100, the camera head 11102 (the imaging unit 11402 thereof), and the like.

While the endoscopic surgery system has been described here as an example, the technology according to the present disclosure may be applied to other systems, for example, a microscopic surgery system.

### 13. Example of Application to Moving Body

The technology according to the present disclosure (the present technology) can be applied to various products. For example, the technology according to the present disclosure may be realized as a device equipped in any type of moving body such as an automobile, an electric vehicle, a hybrid electric vehicle, a motorcycle, a bicycle, a personal mobility device, an airplane, a drone, a ship, and a robot.

FIG. 23 is a block diagram schematically illustrating a configuration example of a vehicle control system that is an example of a moving body control system to which the technology according to the present disclosure is applicable.

A vehicle control system 12000 includes a plurality of electronic control units connected via a communication network 12001. In the example illustrated in FIG. 23, the vehicle control system 12000 includes a drive system control unit 12010, a body system control unit 12020, a vehicle exterior information detection unit 12030, a vehicle interior information detection unit 12040, and an integrated control unit 12050. In addition, as the functional configuration of the integrated control unit 12050, a microcomputer 12051, a sound image output unit 12052, and an in-vehicle network interface (I/F) 12053 are illustrated in the drawing.

The drive system control unit 12010 controls an operation of a device related to a drive system of a vehicle in accordance with various programs. For example, the drive system control unit 12010 functions as a driving force generation device for generating a driving force of a vehicle such as an internal combustion engine or a driving motor, a driving force transmission mechanism for transmitting a driving force to wheels, a steering mechanism for adjusting a turning angle of a vehicle, and a control device such as a braking device that generates a braking force of a vehicle.

The body system control unit 12020 controls operations of various devices mounted in the vehicle body in accordance with various programs. For example, the body system control unit 12020 functions as a control device for a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle having the vehicle control system 12000 mounted thereon. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for people, cars, obstacles, signs, and letters on the road based on the received image.

The imaging unit 12031 is an optical sensor that receives light and outputs an electrical signal according to the amount of received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 may include, for example, a camera that images the driver, and the vehicle interior information detection unit 12040 may calculate the degree of fatigue or concentration of the driver based on detection information input from the driver state detection unit 12041 and may determine whether the driver is dozing or not.

The microcomputer 12051 can calculate a control target value of the driving force generation device, the steering mechanism, or the braking device based on information acquired by the vehicle exterior information detection unit 12030 or the vehicle interior information detection unit 12040 inside and outside the vehicle, and output a control command to the drive system control unit 12010. For example, the microcomputer 12051 can perform coordinated control for realizing an advanced driver assistance system (ADAS) function including vehicle collision avoidance, shock alleviation, following travel based on an inter-vehicle distance, vehicle speed maintenance travel, a vehicle collision warning, or a vehicle lane deviation warning.

Further, the microcomputer 12051 can perform cooperative control for the purpose of automated driving or the like in which autonomous travel is performed without depending on operations of the driver, by controlling the driving force generation device, the steering mechanism, or the braking device and the like based on information about the surroundings of the vehicle, the information being acquired by the vehicle exterior information detection unit 12030 or the vehicle interior information detection unit 12040.

In addition, the microcomputer 12051 can output a control command to the body system control unit 12020 based on the information acquired by the vehicle exterior information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound image output unit 12052 transmits an output signal of at least one of sound and an image to an output device capable of visually or audibly notifying a passenger or the outside of the vehicle of information. In the example of FIG. 23, an audio speaker 12061, a display unit 12062, and an instrument panel 12063 are illustrated as examples of the output device. The display unit 12062 may include at least one of an on-board display and a head-up display, for example.

FIG. 24 is a diagram illustrating an example of the installation position of the imaging unit 12031.

In FIG. 24, a vehicle 12100 includes imaging units 12101, 12102, 12103, 12104, and 12105 as the imaging unit 12031.

The imaging units 12101, 12102, 12103, 12104, and 12105 are provided at positions such as a front nose, side-view mirrors, a rear bumper, a back door, and an upper portion of a windshield in a vehicle interior of the vehicle 12100, for example. The imaging unit 12101 provided on the front nose and the imaging unit 12105 provided in the upper portion of the windshield in the vehicle interior mainly acquire images of the front of the vehicle 12100. The imaging units 12102 and 12103 provided on the side-view mirrors mainly acquire images of a lateral side of the vehicle 12100. The imaging unit 12104 provided on the rear bumper or the back door mainly acquires images of the rear of the vehicle 12100. Front view images acquired by the imaging units 12101 and 12105 are mainly used for detection of preceding vehicles, pedestrians, obstacles, traffic lights, traffic signs, lanes, and the like.

Note that FIG. 24 also illustrates an example of the imaging ranges of the imaging units 12101 to 12104. An imaging range 12111 indicates the imaging range of the imaging unit 12101 provided on the front nose, imaging ranges 12112 and 12113 indicate the imaging ranges of the imaging units 12102 and 12103 provided on the side mirrors, respectively, and an imaging range 12114 indicates the imaging range of the imaging unit 12104 provided on the rear bumper or the back door. For example, an overhead view image of the vehicle 12100 as viewed from above can be obtained by superimposing image data captured by the imaging units 12101 to 12104.

At least one of the imaging units 12101 to 12104 may have a function of obtaining distance information. For example, at least one of the imaging units 12101 to 12104 may be a stereo camera constituted by a plurality of imaging elements or may be an imaging element that has pixels for phase difference detection.

For example, the microcomputer 12051 can obtain a distance to each three-dimensional object within the imaging ranges 12111 to 12114 and changes in the distance over time (relative velocity with respect to the vehicle 12100) based on the distance information obtained from the imaging units 12101 to 12104 to particularly extract, as a preceding vehicle, the closest three-dimensional object on the course of the vehicle 12100, which runs at a predetermined speed (for example, 0 km/h or more) in substantially the same direction as the vehicle 12100. Further, the microcomputer 12051 can set an inter-vehicle distance to be secured in advance in front of the preceding vehicle, and perform automatic brake control (also including following stop control) and automatic acceleration control (also including following start control). Thus, it is possible to perform cooperative control for the purpose of, for example, automated driving in which the vehicle travels in an automated manner without requiring the driver to perform operations.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining whether there is a pedestrian in the captured image of the imaging units 12101 to 12104. Such recognition of the pedestrian is performed using, for example, a procedure for extracting feature points in the captured images of the imaging units 12101 to 12104 serving as infrared cameras, and a procedure for performing pattern matching processing on a series of feature points indicating a contour of an object to determine whether the object is a pedestrian. When the microcomputer 12051 determines that there is a pedestrian in the captured images of the imaging units 12101 to 12104 and the pedestrian is recognized, the sound image output unit 12052 controls the display unit 12062 so that a square contour line for emphasis is superimposed and displayed with the recognized pedestrian. In addition, the sound image output unit 12052 may control the display unit 12062 so that an icon indicating a pedestrian or the like is displayed at a desired position.

An example of the vehicle control system to which the technology according to the present disclosure (the present technology) can be applied has been described above. The technology according to the present disclosure may be applied, for example, to the imaging unit 12031 or the like among the configurations described above. Specifically, the solid-state imaging device according to the present technology can be applied to the imaging unit 12031. By applying the technology according to the present disclosure to the imaging unit 12031, it is possible to improve the performance of the imaging unit 12031.

Note that the present technology are not limited to the above-described embodiments, examples of use, and application examples, and various changes can be made without departing from the gist of the present technology.

Further, the effects described in the present specification are merely exemplary and not intended to be limited, and other effects may be provided as well.

In addition, the present technology can also adopt the following configurations.

[1]

A solid-state imaging device including:
a pixel array unit configured such that a plurality of pixels are arranged two-dimensionally,
wherein each of the plurality of pixels includes at least a polarizer containing a conductive light shielding material, a photoelectric conversion element that performs photoelectric conversion, and a medium,
the medium is disposed around the polarizer, and
the medium has a predetermined refractive index n.

[2]

The solid-state imaging device according to [1], wherein the refractive index n is determined as a refractive index nd in accordance with a wavelength targeted by the polarizer, and
the medium having the determined refractive index nd is formed.

[3]

The solid-state imaging device according to [1] or [2], wherein the refractive index n increases as the wavelength targeted by the polarizer increases.

[4]

The solid-state imaging device according to any one of [1] to [3], wherein the polarizer includes a wire grid made of the conductive light shielding material, and
the refractive index n satisfies the following Formula (1).

λ1(2×P)≤n≤λ2/(2×P) (1)

(In Formula (1), λ1 is a lower limit wavelength in a range of the wavelength targeted by the polarizer, λ2 is an upper limit wavelength in a range of the wavelength targeted by the polarizer, and λ1 and λ2 are different from each other. Note that λ1 and λ2 may be the same, and the wavelength targeted by the polarizer may be λ1 or λ2. P indicates a pitch of the wire grid.)

[5]

The solid-state imaging device according to [4], wherein λ1 and λ2 in each of at least two of the pixels among the plurality of pixels are different from each other.

[6]

The solid-state imaging device according to any one of [1] to [5], wherein the polarizer has a structure for generating light having at least two types of polarization states.

[7]

The solid-state imaging device according to any one of [1] to [6], wherein the photoelectric conversion element includes an inorganic photoelectric conversion film.

[8]

The solid-state imaging device according to any one of [1] to [7], wherein the photoelectric conversion element includes an organic photoelectric conversion film.

[9]

The solid-state imaging device according to any one of [1] to [8], wherein the pixel includes the polarizer and the photoelectric conversion element in order from a light incident side.

[10]

The solid-state imaging device according to any one of [1] to [9], wherein at least a portion of the photoelectric conversion element is the medium, and the polarizer is formed on a back surface of the photoelectric conversion element on a light incident side.

[11]

The solid-state imaging device according to any one of [1] to [9], wherein at least a portion of the photoelectric conversion element is the medium, and the polarizer is formed to be embedded in the photoelectric conversion element.

[12]

The solid-state imaging device according to any one of [1] to [9], wherein at least a portion of the photoelectric conversion element is the medium,
the polarizer is formed on a back surface of the photoelectric conversion element on a light incident side, and
the polarizer is formed on a front surface of the photoelectric conversion element on a side opposite to the light incident side.

[13]

A solid-state imaging device including:
a pixel array unit configured such that a plurality of first pixels and at least one second pixel are arranged two-dimensionally,
wherein each of the plurality of first pixels includes a photoelectric conversion element that performs photoelectric conversion,
the at least one second pixel includes a polarizer containing a conductive light shielding material, a photoelectric conversion element that performs photoelectric conversion, and a medium,
a medium is disposed around the polarizer, and
the medium has a predetermined refractive index n.

[14]

The solid-state imaging device according to [13], wherein the refractive index n is determined as a refractive index nd in accordance with a wavelength targeted by the polarizer, and
the medium having the determined refractive index nd is formed.

[15]

The solid-state imaging device according to [13] or [14], wherein the predetermined refractive index n increases as the wavelength targeted by the polarizer increases.

[16]

The solid-state imaging device according to any one of [13] to [15], wherein the polarizer includes a wire grid made of the conductive light shielding material, and
the refractive index n satisfies the following Formula (1).

λ1/(2×P)≤n≤λ2/(2×P) (1)

(In Formula (1), λ1 is a lower limit wavelength in a range of the wavelength targeted by the polarizer, λ2 is an upper limit wavelength in a range of the wavelength targeted by the polarizer, and λ1 and λ2 are different from each other. Note that λ1 and λ2 may be the same, and the wavelength targeted by the polarizer may be Xl or λ2. P indicates a pitch of the wire grid.)

[17]

The solid-state imaging device according to [16], wherein the at least one second pixel is constituted by a plurality of the second pixels, and
λ1 and λ2 in each of at least two of the second pixels among the plurality of second pixels are different from each other.

[18]

The solid-state imaging device according to any one of [13] to [17], wherein the polarizer has a structure for generating light having at least two types of polarization states.

[19]

The solid-state imaging device according to any one of [13] to [18], wherein the photoelectric conversion element includes an inorganic photoelectric conversion film.

[20]

The solid-state imaging device according to any one of [13] to [19], wherein the photoelectric conversion element includes an organic photoelectric conversion film.

[21]

The solid-state imaging device according to any one of [13] to [20], wherein the at least one second pixel includes the polarizer and the photoelectric conversion element in order from a light incident side.

[22]

The solid-state imaging device according to any one of [13] to [21], wherein at least a portion of the photoelectric conversion element is the medium, and the polarizer is formed on a back surface of the photoelectric conversion element on a light incident side.

[23]

The solid-state imaging device according to any one of [13] to [21], wherein at least a portion of the photoelectric conversion element is the medium, and the polarizer is formed to be embedded in the photoelectric conversion element.

[24]

The solid-state imaging device according to any one of [13] to [21], wherein at least a portion of the photoelectric conversion element is the medium, the polarizer is formed on a back surface of the photoelectric conversion element on a light incident side, and
the polarizer is formed on a front surface of the photoelectric conversion element on a side opposite to the light incident side.

[25]

Electronic equipment equipped with the solid-state imaging device according to any one of [1] to [24].

### REFERENCE SIGNS LIST

1, 1-7-1, 1-7-2, 1-7-3, 1-7-4, 1-8-1, 1-8-2, 1-8-3, 1-8-4 Medium
2 Photoelectric conversion element
3 (3G, 3R) Color filter
4 On-chip lens
10, 10-1 (10-1-1, 10-1-2), 10-2 (10-2-1, 10-2-2), 10-3 (10-3-1, 10-3-2), 10-4 (10-4-1, 10-4-2), 10-5 (10-5-1, 10-5-2), 10-6 (10-6-1, 10-6-2), 10-7 (10-7-1, 10-7-2, 10-7-3, 10-7-4), 10-8 (10-8-1, 10-8-2, 10-8-3, 10-8-4) Wire grid polarizer
11 Wire
31, 32 Wire grid upper film
101, 102, 103, 104, 105, 106, 107, 108, 1M, 1F, 211G Solid-state imaging device
P1-1, P1-2, P2-1, P2-2, P3-1, P3-2, P4-1, P4-2, P5-1, P5-2, P6-1, P6-2, P7-1, P7-2, P7-3, P7-4, P8-1, P8-2, P8-3, P8-4, 2M Pixel
P Pitch

1. A solid-state imaging device comprising:
a pixel array unit configured such that a plurality of pixels are arranged two-dimensionally,
wherein each of the plurality of pixels includes at least a polarizer containing a conductive light shielding material, a photoelectric conversion element that performs photoelectric conversion, and a medium,
the medium is disposed around the polarizer, and
the medium has a predetermined refractive index n.

2. The solid-state imaging device according to claim 1, wherein the refractive index n is determined as a refractive index nd in accordance with a wavelength targeted by the polarizer, and
the medium having the determined refractive index nd is formed.

3. The solid-state imaging device according to claim 1, wherein the refractive index n increases as the wavelength targeted by the polarizer increases.

4. The solid-state imaging device according to claim 1, wherein the polarizer includes a wire grid made of the conductive light shielding material, and the refractive index n satisfies the following Formula (1).
λ1(2×P)≤n≤λ2/(2×P) (1)
(In Formula (1), λ1 is a lower limit wavelength in a range of the wavelength targeted by the polarizer, λ2 is an upper limit wavelength in a range of the wavelength targeted by the polarizer, and λ1 and λ2 are different from each other. Note that λ1 and λ2 may be the same, and the wavelength targeted by the polarizer may be λ1 or λ2. P indicates a pitch of the wire grid.)

5. The solid-state imaging device according to claim 4, wherein λ1 and λ2 in each of at least two of the pixels among the plurality of pixels are different from each other.

6. The solid-state imaging device according to claim 1, wherein the polarizer has a structure for generating light having at least two types of polarization states.

7. The solid-state imaging device according to claim 1, wherein the photoelectric conversion element includes an inorganic photoelectric conversion film.

8. The solid-state imaging device according to claim 1, wherein the photoelectric conversion element includes an organic photoelectric conversion film.

9. The solid-state imaging device according to claim 1, wherein the pixel includes the polarizer and the photoelectric conversion element in order from a light incident side.

10. The solid-state imaging device according to claim 1, wherein at least a portion of the photoelectric conversion element is the medium, and
the polarizer is formed on a back surface of the photoelectric conversion element on a light incident side.

11. The solid-state imaging device according to claim 1, wherein at least a portion of the photoelectric conversion element is the medium, and
the polarizer is formed to be embedded in the photoelectric conversion element.

12. The solid-state imaging device according to claim 1, wherein at least a portion of the photoelectric conversion element is the medium,
the polarizer is formed on a back surface of the photoelectric conversion element on a light incident side, and
the polarizer is formed on a front surface of the photoelectric conversion element on a side opposite to the light incident side.

13. A solid-state imaging device comprising:
a pixel array unit configured such that a plurality of first pixels and at least one second pixel are arranged two-dimensionally,
wherein each of the plurality of first pixels includes a photoelectric conversion element that performs photoelectric conversion,
the at least one second pixel includes a polarizer containing a conductive light shielding material, a photoelectric conversion element that performs photoelectric conversion, and a medium,
a medium is disposed around the polarizer, and
the medium has a predetermined refractive index n.

14. The solid-state imaging device according to claim 13, wherein the refractive index n is determined as a refractive index nd in accordance with a wavelength targeted by the polarizer, and
the medium having the determined refractive index nd is formed.

15. The solid-state imaging device according to claim 13, wherein the predetermined refractive index n increases as the wavelength targeted by the polarizer increases.

16. The solid-state imaging device according to claim 13, wherein the polarizer includes a wire grid made of the conductive light shielding material, and the refractive index n satisfies the following Formula (1).
λ1/(2×P)≤n≤λ2/(2×P) (1)
(In Formula (1), λ1 is a lower limit wavelength in a range of the wavelength targeted by the polarizer, λ2 is an upper limit wavelength in a range of the wavelength targeted by the polarizer, and λ1 and λ2 are different from each other. Note that λ1 and λ2 may be the same, and the wavelength targeted by the polarizer may be λ1 or λ2. P indicates a pitch of the wire grid.)

17. The solid-state imaging device according to claim 16, wherein the at least one second pixel is constituted by a plurality of the second pixels, and λ1 and λ2 in each of at least two of the second pixels among the plurality of second pixels are different from each other.

18. The solid-state imaging device according to claim 13, wherein the polarizer has a structure for generating light having at least two types of polarization states.

19. The solid-state imaging device according to claim 13, wherein the photoelectric conversion element includes an inorganic photoelectric conversion film.

20. The solid-state imaging device according to claim 13, wherein the photoelectric conversion element includes an organic photoelectric conversion film.

21. The solid-state imaging device according to claim 13, wherein the at least one second pixel includes the polarizer and the photoelectric conversion element in order from a light incident side.

22. The solid-state imaging device according to claim 13, wherein at least a portion of the photoelectric conversion element is the medium, and
the polarizer is formed on a back surface of the photoelectric conversion element on a light incident side.

23. The solid-state imaging device according to claim 13, wherein at least a portion of the photoelectric conversion element is the medium, and
the polarizer is formed to be embedded in the photoelectric conversion element.

24. The solid-state imaging device according to claim 13, wherein at least a portion of the photoelectric conversion element is the medium,
the polarizer is formed on a back surface of the photoelectric conversion element on a light incident side, and
the polarizer is formed on a front surface of the photoelectric conversion element on a side opposite to the light incident side.

25. Electronic equipment equipped with the solid-state imaging device according to claim 1.

26. Electronic equipment equipped with the solid-state imaging device according to claim 13.
